(19) United States
(12) Patent Application Publication
(10) Pub. No.: US 2026/0312359 A1
(43) Pub. Date: Oct. 8, 2026

(54) SURFACE EMITTING DEVICE AND MANUFACTURING METHOD OF SURFACE EMITTING DEVICE

(71) Applicant: Sony Semiconductor Solutions Corporation, Kanagawa (JP)

(72) Inventor: Jugo MITOMO, Kanagawa (JP)

(21) Appl. No.: 19/485,011

(22) PCT Filed: May 20, 2024
(86) PCT No.: PCT/JP2024/018434

§ 371 Date: Nov. 17, 2025

(30) Foreign Application Priority Data
Jun. 28, 2023 (JP) 2023-105877

(51) Int. Cl. H01S 5/02315; H01S 5/042; H01S 5/183

(52) U.S. Cl. CPC H01S 5/02315; H01S 5/04256; H01S 5/183

(57) ABSTRACT

To provide a surface emitting device that can suppress deformation of a surface emitting element at the time when the surface emitting element is mounted on a mounting substrate.

A surface emitting device according to the present technology is a surface emitting device including: a surface emitting element including an element region and a peripheral region around the element region; and a mounting substrate on which the surface emitting element is mounted, in which the element region includes a light emitting element part provided with an electrode on the mounting substrate side, the electrode is bonded to the mounting substrate with a bump interposed between the electrode and the mounting substrate, and the peripheral region and the mounting substrate have a spacer provided between the peripheral region and the mounting substrate.

### TECHNICAL FIELD

The technology according to the present disclosure (hereinafter also referred to as “the present technology”) relates to a surface emitting device and a manufacturing method of the surface emitting device.

### BACKGROUND ART

Conventionally, a semiconductor device including a semiconductor element and a mounting substrate on which the semiconductor element is mounted (for example, flip-chip mounted) is known (see, for example, Patent Documents 1 and 2).

### CITATION LIST

### Patent Document

Patent Document 1: Japanese Patent Application Laid-Open No. H8-288336

Patent Document 2: Japanese Patent Application Laid-Open No. 2001-35872

### SUMMARY OF THE INVENTION

### Problems to be Solved by the Invention

However, Patent Documents 1 and 2 do not mention at all that the semiconductor element is deformed at the time when the semiconductor element is mounted on the mounting substrate.

Therefore, a main object of the present technology is to provide a surface emitting device that can suppress deformation of a surface emitting element at the time when the surface emitting element is mounted on a mounting substrate.

### Solutions to Problems

The present technology provides a surface emitting device including:
a surface emitting element including an element region and a peripheral region around the element region; and
a mounting substrate on which the surface emitting element is mounted, in which
the element region includes a light emitting element part provided with an electrode on a mounting substrate side,
the electrode is bonded to the mounting substrate with a bump interposed between the electrode and the mounting substrate, and
the peripheral region and the mounting substrate have a spacer provided between the peripheral region and the mounting substrate.

The spacer may be interposed between an outermost peripheral portion of the peripheral region and the mounting substrate. The peripheral region may have the dummy element part.

The dummy element part may include the outermost peripheral portion.

The outermost peripheral portion may extend along at least a part of an outer periphery of the element region, and the spacer may be provided along at least a part of the outermost peripheral portion in an extending direction.

The outermost peripheral portion may extend along an entire circumference of an outer periphery of the element region.

The spacer may have a plurality of portions aligned in the extending direction.

The spacer may include a dummy bump.

The surface emitting element may have an emission surface which is a surface on an opposite side to the mounting substrate side, the emission surface being a flat surface.

The surface emitting element may have a modified layer on a side surface.

With respect to a direction orthogonal to an in-plane direction, the electrode may have a surface on the mounting substrate side, the surface being located closer to the mounting substrate than a surface of the outermost peripheral portion of the peripheral region on the mounting substrate side, and the spacer may have a thickness that is thicker than a thickness of the bump.

The peripheral region may have a dummy element part and the element region may have a dummy element part, the dummy element part of the peripheral region and/or the dummy element part of the element region having the mounting substrate side provided with another electrode, and the another electrode may be bonded to the mounting substrate with another bump interposed between the another electrode and the mounting substrate.

The element region may include a plurality of the light emitting element parts separated in an in-plane direction, and the another electrode may be a common electrode provided in common for the plurality of light emitting element parts.

Each of the bump and the dummy bump may include a material that is not easily crushed by pressurization.

The bump and the dummy bump may include the same conductive material.

The peripheral region may include a dummy element part, and each of the light emitting element part and the dummy element part may include first and second semiconductor structures laminated on each other, and a light emitting layer disposed between the first and second semiconductor structures.

The present technology also provides a manufacturing method of a surface emitting device, the manufacturing method including: a step of forming a surface emitting element including an element region having a light emitting element part and a peripheral region of the element region; and
a step of interposing a spacer between the peripheral region and a mounting substrate and bonding an electrode provided on a mounting substrate side of the light emitting element part and the mounting substrate with a bump interposed between the electrode and the mounting substrate.

The spacer may include a dummy bump.

The step of bonding may be performed by pressing an emission surface toward the mounting substrate side, the emission surface being a surface of the surface emitting element on an opposite side to the mounting substrate side.

In the step of forming, a plurality of the surface emitting elements may be collectively formed such that the peripheral regions are adjacent to each other, and after the step of forming and before the step of bonding, the manufacturing method may include a step of singulating the plurality of surface emitting elements by stealth dicing along a boundary between the peripheral regions that are adjacent to each other.

### BRIEF DESCRIPTION OF DRAWINGS

FIG. 1 is a cross-sectional view (part 1) of a surface emitting device according to Example 1 of one embodiment of the present technology.

FIG. 2 is a cross-sectional view (part 2) of the surface emitting device according to Example 1 of one embodiment of the present technology.

FIG. 3 is a bottom view of the surface emitting device according to Example 1 of one embodiment of the present technology in a state where a mounting substrate is omitted.

FIG. 4 is a flowchart for explaining an example of a manufacturing method of the surface emitting device according to Example 1 of one embodiment of the present technology.

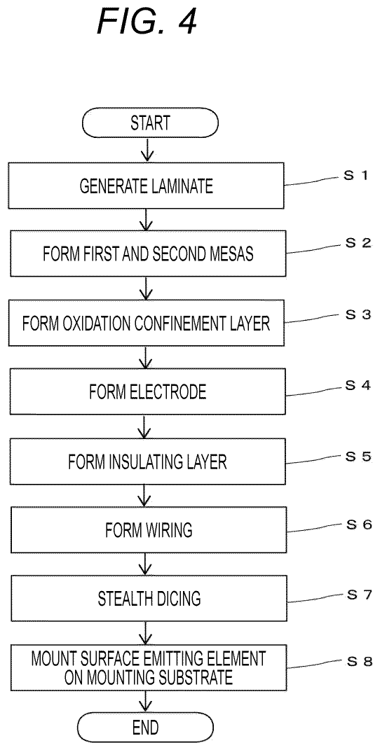

FIG. 5 is a process cross-sectional view of an example of the manufacturing method of the surface emitting device according to Example 1 of one embodiment of the present technology.

FIG. 6 is a process cross-sectional view of an example of the manufacturing method of the surface emitting device according to Example 1 of one embodiment of the present technology.

FIG. 7 is a process cross-sectional view of an example of the manufacturing method of the surface emitting device according to Example 1 of one embodiment of the present technology.

FIG. 8 is a process cross-sectional view of an example of the manufacturing method of the surface emitting device according to Example 1 of one embodiment of the present technology.

FIG. 9 is a process cross-sectional view of an example of the manufacturing method of the surface emitting device according to Example 1 of one embodiment of the present technology.

FIG. 10 is a process cross-sectional view of an example of the manufacturing method of the surface emitting device according to Example 1 of one embodiment of the present technology.

FIG. 11 is a process cross-sectional view of an example of the manufacturing method of the surface emitting device according to Example 1 of one embodiment of the present technology.

FIG. 12 is a process perspective view of an example of the manufacturing method of the surface emitting device according to Example 1 of one embodiment of the present technology.

FIG. 13 is a process cross-sectional view of an example of the manufacturing method of the surface emitting device according to Example 1 of one embodiment of the present technology.

FIG. 14 is a process cross-sectional view of an example of the manufacturing method of the surface emitting device according to Example 1 of one embodiment of the present technology.

FIG. 15 is a process cross-sectional view of an example of the manufacturing method of the surface emitting device according to Example 1 of one embodiment of the present technology.

FIG. 16 is a process cross-sectional view of an example of the manufacturing method of the surface emitting device according to Example 1 of one embodiment of the present technology.

FIG. 17 is a process cross-sectional view of an example of the manufacturing method of the surface emitting device according to Example 1 of one embodiment of the present technology.

FIG. 18 is a process perspective view of an example of the manufacturing method of the surface emitting device according to Example 1 of one embodiment of the present technology.

FIG. 19A is a diagram for explaining a defect at the time of bump bonding of a surface emitting device according to a comparative example. FIG. 19B is a diagram for explaining an action at the time of bump bonding of the surface emitting device according to the present technology.

FIG. 20 is a cross-sectional view of a surface emitting device according to Example 2 of one embodiment of the present technology.

FIG. 21 is a cross-sectional view of a surface emitting device according to Example 3 of one embodiment of the present technology.

FIG. 22 is a bottom view of the surface emitting device according to Example 3 of one embodiment of the present technology in a state where a mounting substrate is omitted.

FIG. 23 is a cross-sectional view of a surface emitting device according to Example 4 of one embodiment of the present technology.

FIG. 24 is a bottom view of the surface emitting device according to Example 4 of one embodiment of the present technology in a state where a mounting substrate is omitted.

FIG. 25 is a cross-sectional view of a surface emitting device according to Example 5 of one embodiment of the present technology.

FIG. 26 is a cross-sectional view of a surface emitting device according to Example 6 of one embodiment of the present technology.

FIG. 27 is a cross-sectional view of a surface emitting device according to Example 7 of one embodiment of the present technology.

FIG. 28 is a cross-sectional view of a surface emitting device according to Example 8 of one embodiment of the present technology.

FIG. 29 is a bottom view of a surface emitting device according to Example 9 of one embodiment of the present technology in a state where a mounting substrate is omitted.

FIG. 30 is a bottom view of a surface emitting device according to Example 10 of one embodiment of the present technology in a state where a mounting substrate is omitted.

FIG. 31 is a bottom view of a surface emitting device according to Example 11 of one embodiment of the present technology in a state where a mounting substrate is omitted.

FIG. 32 is a bottom view of a surface emitting device according to Example 12 of one embodiment of the present technology in a state where a mounting substrate is omitted.

FIG. 33 is a cross-sectional view of a surface emitting device according to Example 13 of one embodiment of the present technology.

FIG. 34 is a cross-sectional view of a surface emitting device according to Example 14 of one embodiment of the present technology.

FIG. 35 is a comparative reference view used for explaining the surface emitting device according to Example 1 of one embodiment of the present technology.

FIG. 36 is a cross-sectional view illustrating a light emitting element part of a modification.

FIG. 37 is a diagram illustrating an application example of a surface emitting laser device according to Example 1 of one embodiment of the present technology to a distance measurement device.

FIG. 38 is a block diagram illustrating an example of a schematic configuration of a vehicle control system.

FIG. 39 is an explanatory diagram illustrating an example of installation positions of distance measurement devices.

### MODE FOR CARRYING OUT THE INVENTION

Hereinafter, a preferred embodiment of the present technology will be described in detail with reference to the accompanying drawings. Note that, in the present description and drawings, constituent elements having substantially the same functional configuration are denoted by the same reference numerals, and redundant description is omitted. The embodiment described hereinafter illustrates a representative embodiment of the present technology, and the scope of the present technology is not narrowly interpreted by this. In the present description, even in a case where a surface emitting device and a manufacturing method of the surface emitting device according to the present technology each exert a plurality of effects, each of the surface emitting device and the manufacturing method of the surface emitting device according to the present technology is only required to exert at least one of the effects. The effects described in the present description are merely examples and are not limiting, and other effects may be present.

Furthermore, the description will be given in the following order.
0. Introduction
1. Surface emitting device according to Example 1 of one embodiment of the present technology
2. Surface emitting device according to Example 2 of one embodiment of the present technology
3. Surface emitting device according to Example 3 of one embodiment of the present technology
4. Surface emitting device according to Example 4 of one embodiment of the present technology
5. Surface emitting device according to Example 5 of one embodiment of the present technology
6. Surface emitting device according to Example 6 of one embodiment of the present technology
7. Surface emitting device according to Example 7 of one embodiment of the present technology
8. Surface emitting device according to Example 8 of one embodiment of the present technology
9. Surface emitting device according to Example 9 of one embodiment of the present technology
10. Surface emitting device according to Example 10 of one embodiment of the present technology
11. Surface emitting device according to Example 11 of one embodiment of the present technology
12. Surface emitting device according to Example 12 of one embodiment of the present technology
13. Surface emitting device according to Example 13 of one embodiment of the present technology
14. Surface emitting device according to Example 14 of one embodiment of the present technology
15. Modification of the present technology
16. Application example for electronic apparatus
17. Example in which surface emitting device is applied to distance measurement device
18. Example in which distance measurement device is mounted on mobile body

### 0. Introduction

Conventionally, there is known a semiconductor device including a semiconductor element (semiconductor chip) including an element region and a peripheral region thereof and a mounting substrate (for example, a drive substrate, a wiring substrate, or the like) on which the semiconductor element is flip-chip mounted (see, for example, Patent Documents 1 and 2).

In general, a plurality of semiconductor devices is collectively formed on one wafer, and then singulated into individual semiconductor devices by dicing.

In the conventional semiconductor device, an element part as a structure included in the element region is bonded to a mounting substrate with a bump interposed therebetween, but a structure serving as a spacer is not interposed between the peripheral region and the mounting substrate.

The inventor has found that, in the conventional semiconductor device, when the entire semiconductor element is pressed against the mounting substrate side during flip-chip mounting (during bump bonding), a problem occurs in which the peripheral region where no structure is interposed between the semiconductor element and the mounting substrate is pressed against the mounting substrate side, and the element (chip) is deformed (deflected). That is, the inventor has found the problem that the semiconductor element is deformed (elastically deformed) due to the presence of a gap between the mounting substrate and the peripheral region of the element region of the semiconductor element. When the semiconductor element is deformed at the time of bump bonding, a tensile stress is applied to the semiconductor element after the bump bonding, which leads to element breakage and lowering in reliability.

Therefore, as a result of intensive studies, the inventor has developed a surface emitting device according to the present technology as a surface emitting device that can suppress deformation (elastic deformation) of a surface emitting element at the time of mounting the surface emitting element on a mounting substrate (at the time of bump bonding).

Specifically, the inventor has succeeded in suppressing the deformation (elastic deformation) at the time of mounting the surface emitting element on the mounting substrate by interposing a structure serving as a spacer between the peripheral region of the element region of the surface emitting element and the mounting substrate.

The above problem becomes more serious as the area of a dicing region which is the outermost peripheral portion of the peripheral region becomes larger. For example, in a case where the dicing is performed by stealth dicing, the area of a laser irradiation area as the dicing region needs to be secured to some extent.

Therefore, in order to solve this problem, it is conceivable to provide some structure in the laser irradiation area in advance before stealth dicing, but in that case, because laser light is scattered, absorbed, and the like by the structure at the time of stealth dicing, it becomes difficult to accurately perform the stealth dicing.

Therefore, for example, at the time of performing the dicing by stealth dicing, the inventor has succeeded in accurately performing the stealth dicing and suppressing deformation at the time of mounting the surface emitting element on the mounting substrate (at the time of bump bonding) by forming a structure to be a spacer in the laser irradiation area after stealth dicing.

Hereinafter, some examples of one embodiment of a surface emitting element according to the present technology will be described by using the drawings.

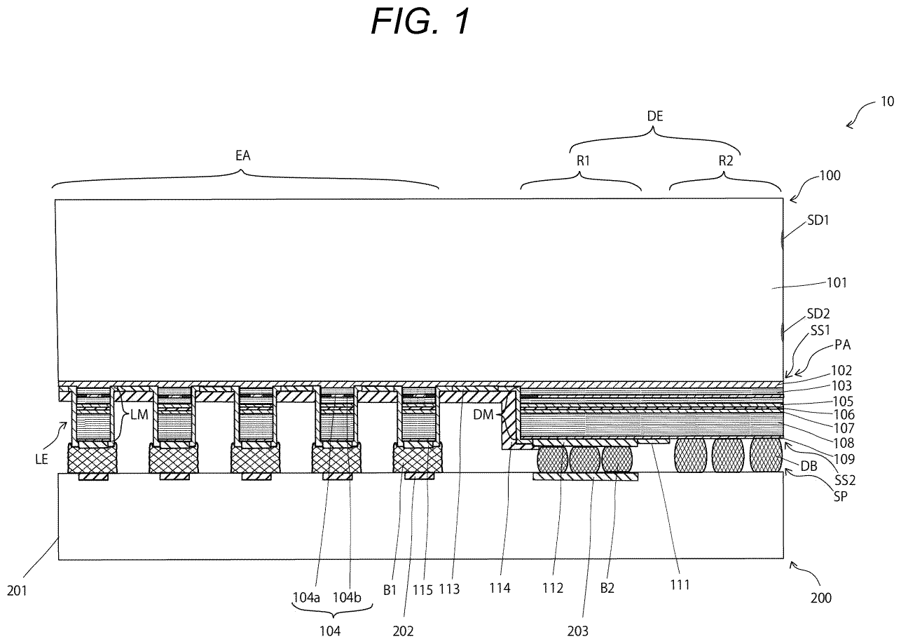

Hereinafter, in the cross-sectional view of FIG. 1 and the like, the upper side will be described as “upper” and the lower side will be described as “lower” as appropriate.

### 1. Surface Emitting Device According to Example 1 of One Embodiment of the Present Technology

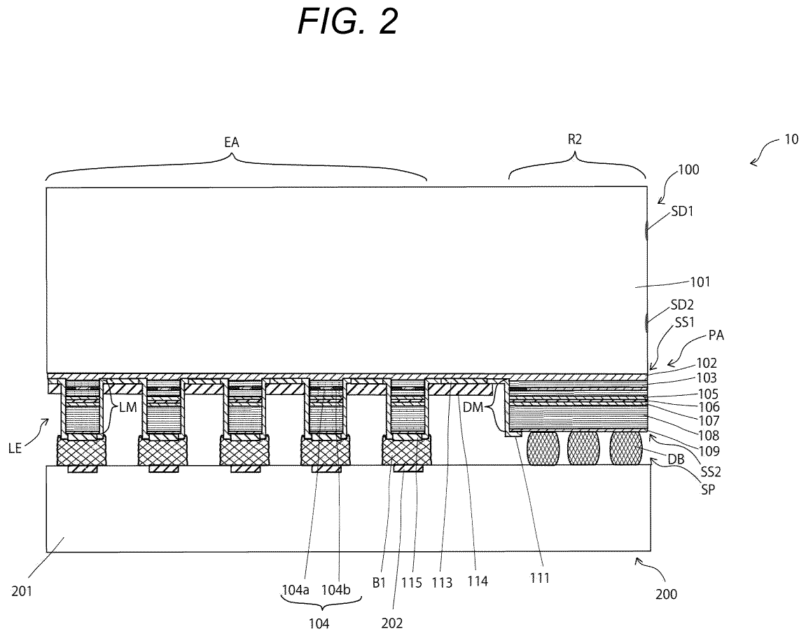

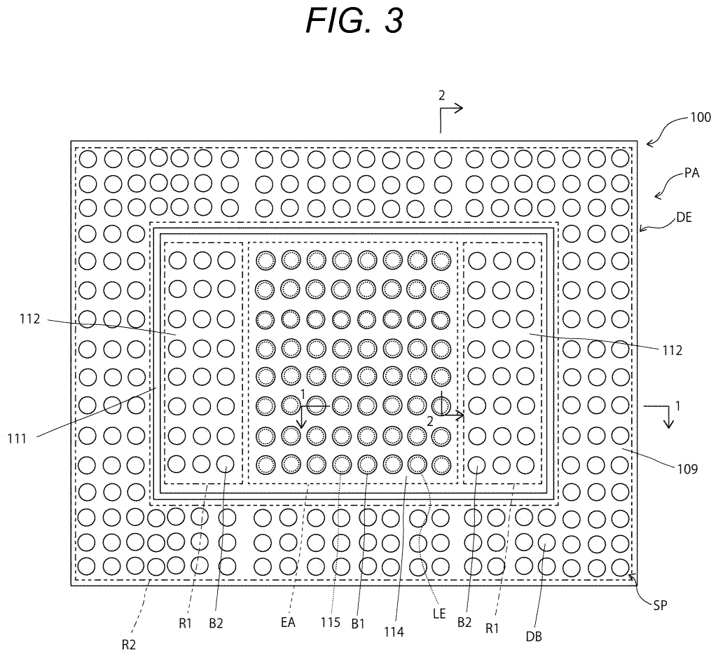

FIG. 1 is a cross-sectional view (part 1) of a surface emitting device 10 according to Example 1 of one embodiment of the present technology. FIG. 2 is a cross-sectional view (part 2) of the surface emitting device 10 according to Example 1 of one embodiment of the present technology. FIG. 3 is a bottom view of the surface emitting device 10 according to Example 1 of one embodiment of the present technology in a state where a mounting substrate is omitted. FIG. 1 is a cross-sectional view taken along a line 1-1 in FIG. 3. FIG. 2 is a cross-sectional view taken along a line 2-2 in FIG. 3.

### <<Configuration of Surface Emitting Device>>

### (Overall Configuration of Surface Emitting Device)

As an example, as illustrated in FIGS. 1 and 2, the surface emitting device 10 according to the present technology includes a surface emitting element 100 and a mounting substrate 200 on which the surface emitting element 100 is mounted.

As an example, the surface emitting element 100 has a chip shape and is also referred to as a “surface emitting chip”. As an example, the surface emitting element 100 is flip-chip mounted on the mounting substrate 200. The flip-chip mounting is also referred to as “junction-down mounting” or “face-down mounting”.

As an example, the surface emitting element 100 is driven by a driver (drive circuit). As an example, the mounting substrate 200 is a drive substrate having a driver (drive circuit) or a wiring substrate connected to the driver (drive circuit).

As illustrated in FIGS. 1 to 3, the surface emitting element 100 includes an element region EA and a peripheral region PA of the element region EA. As an example, the element region EA and the peripheral region PA are separated in the in-plane direction.

As an example, as illustrated in FIG. 3, the element region EA includes a plurality (for example, 64 pieces) of light emitting element parts LE arranged apart from each other in the in-plane direction. As an example, the plurality of light emitting element parts LE is arranged in a two-dimensional array shape (for example, a matrix shape) in the in-plane direction to constitute a light emitting element part array.

As an example, the peripheral region PA includes a dummy element part DE. As an example, in the bottom view (the plan view, this similarly applies hereinafter), the dummy element part DE includes two first regions R1 and R1 that sandwich the element region EA in the 1-1 line direction in FIG. 3 and a second region R2 (an outermost peripheral portion of the peripheral region PA) having a shape of a circumference in the bottom view (for example, a rectangular frame shape in the bottom view) surrounding a region including the element region EA and the two first regions R1 and R1.

As an example, each light emitting element part LE is a back surface emission type surface emitting laser (VCSEL: Vertical Cavity Surface Emitting Laser). Each of the light emitting element parts LE emits light to the opposite side to the mounting substrate 200 side (back surface side (upper surface side) of a substrate 101 described later).

As illustrated in FIGS. 1 and 2, each of the light emitting element parts LE and the dummy element part DE includes the substrate 101, first and second semiconductor structures SS1 and SS2 laminated on the substrate 101, and a light emitting layer 106 disposed between the first and second semiconductor structures SS1 and SS2. That is, each light emitting element part LE and the dummy element part DE have substantially the same laminated structure.

The first and second semiconductor structures SS1 and SS2 have different conductivity types. Each of the light emitting element parts LE has a double heterostructure in which the light emitting layer 106 is sandwiched between the first and second semiconductor Structures SS1 and SS2 having different conductivity types in the laminating direction (the vertical direction, a direction orthogonal to the in-plane direction), and can cause holes and electrons to undergo light-emitting recombination (radiation recombination) in the light emitting layer 106.

As an example, the first semiconductor structure SS1 includes a first contact layer 102 disposed on the substrate 101, a first semiconductor multilayer film reflector 103 disposed on the first contact layer 102, and a first cladding layer 105 disposed on the first semiconductor multilayer film reflector 103. As an example, an oxidation confinement layer 104 is disposed in the first semiconductor multilayer film reflector 103. As an example, a part (lower part) of the substrate 101 and the first contact layer 102 is shared by each of the light emitting element parts LE and the dummy element part DE.

As an example, the second semiconductor structure SS2 includes a second cladding layer 107 disposed on the light emitting layer 106, a second semiconductor multilayer film reflector 108 disposed on the second cladding layer 107, and a second contact layer 109 disposed on the second semiconductor multilayer film reflector 108.

That is, as an example, in the surface emitting element 100, the first contact layer 102, the first semiconductor multilayer film reflector 103 having the oxidation confinement layer 104 disposed therein, the first cladding layer 105, the light emitting layer 106, the second cladding layer 107, the second semiconductor multilayer film reflector 108, and the second contact layer 109 are laminated on the substrate 101 in this order.

Each of the light emitting element parts LE includes the light emitting layer 106 and the first and second semiconductor multilayer film reflectors 103 and 108 sandwiching the light emitting layer 106 in the laminating direction (vertical direction) to form a resonator. As an example, a resonator length of the resonator is an integral multiple of a half wavelength (λ/2) of a standing wave generated in the resonator. Here, λ is a light emission wavelength of the light emitting element part LE.

As an example, each of the light emitting element parts LE and the dummy element part DE includes a mesa. Hereinafter, the mesa of the light emitting element part LE is also referred to as a light emitting mesa LM, and the mesa of the dummy element part DE is also referred to as a dummy mesa DM. The dummy mesa is also referred to as a “pedestal part”.

As an example, each of the light emitting mesa LM and the dummy mesa DM is formed while including a part (upper part) of the first contact layer 102, the first semiconductor multilayer film reflector 103 having the oxidation confinement layer 104 disposed therein, the first cladding layer 105, the light emitting layer 106, the second cladding layer 107, the second semiconductor multilayer film reflector 108, and the second contact layer 109.

As an example, each of the light emitting mesa LM and the dummy mesa DM has a height of several um to several tens of μm (for example, about 3 to 10 μm). The difference in height between the light emitting mesa LM and the dummy mesa DM is preferably as small as possible. Here, the plan view shape of the light emitting mesa LM is circular (see FIG. 3), but may be, for example, an elliptical shape or a polygonal shape such as a square, a rectangle, a hexagon, or an octagon. Here, the plan view shape (bottom view shape) of the dummy mesa DM is a rectangular frame shape (see FIG. 3), but may be, for example, an annular shape, an elliptical annular shape, a polygonal frame shape other than the rectangular frame shape, or the like.

In each of the light emitting element parts LE, as an example, a cathode electrode 115 (electrode) is provided on the mounting substrate 200 side. As an example, each of the cathode electrodes 115 is provided in a solid form on the second contact layer 109 of the corresponding light emitting element part LE. As an example, each of the cathode electrodes 115 is bonded to the mounting substrate 200 with a first bump B1 (bump) interposed therebetween. Each of the cathode electrodes 115 includes, for example, Au/Ni/AuGe or the like.

As illustrated in FIG. 1, as an example, in the first region R1 of the dummy element part DE, an anode electrode 112 (another electrode) is provided on the mounting substrate 200 side. As an example, the anode electrode 112 is provided in a solid form on the second contact layer 109 in the first region R1 of the dummy element part DE. As an example, the anode electrode 112 is bonded to the mounting substrate 200 with a plurality of second bumps B2 (other bumps) interposed therebetween. The anode electrode 112 is a common electrode provided in common for the plurality of light emitting element parts LE. The anode electrode 112 includes, for example, Au/Pt/Ti, or the like.

As an example, in the first contact layer 102, a region between the element region EA and the peripheral region PA and a region between adjacent light emitting element parts LE are covered with an intermediate electrode 113. The intermediate electrode 113 includes, for example, Au/Pt/Ti, or the like.

As an example, the side surface and the lower surface (the top of the dummy mesa DM) of the first region R1 of the dummy element part DE and the side surface of each of the light emitting element parts LE of the element region EA are covered with an insulating film 111. The insulating film 111 includes, for example, a dielectric such as SiO2, SiN, or SiON.

As an example, the intermediate electrode 113 and the insulating film 111 provided on the side surface and the lower surface of the first region R1 of the dummy element part DE are covered with wiring 114. An end of a portion of the wiring 114 provided on the lower surface of the first region R1 is in contact with the anode electrode 112. That is, the anode electrode 112 is connected to the intermediate electrode 113 via the wiring 114. The wiring 114 includes, for example, conductive plating. The conductive plating includes, for example, Au, Ag, Cu, or the like.

As is clear from the above description, in the surface emitting device 10, the surface emitting element 100 has an electrode layout common to the anode and independent of the cathode with respect to the mounting substrate 200, and each of the light emitting element parts LE can be independently driven by the driver.

### (Substrate)

As an example, the substrate 101 includes GaAs (for example, SI (semi-insulating)-GaAs).

### (First Contact Layer)

The first contact layer 102 is a semiconductor layer having high carrier conductivity and low resistance and, as an example, includes a p-GaAs layer highly doped with p-type impurities. Examples of the p-type impurities (dopant) include, for example, Zn, Mg, Be, C, and the like. The contact layer is also referred to as a “current injection layer”. In the first contact layer 102 of the light emitting element part LE, a lateral Current path is formed.

### (First Semiconductor Multilayer Film Reflector)

As an example, the first semiconductor multilayer film reflector 103 is a semiconductor multilayer film reflector doped with p-type impurities, has low light absorption, and has high reflectance and conductivity. The semiconductor multilayer film reflector has a structure in which a plurality of types (for example, two types) of semiconductor layers (for example, p-AlGaAs layers) having different refractive indexes is alternately laminated with an optical thickness of ¼ wavelength of the emission wavelength A. Examples of the p-type impurities (dopant) include, for example, Zn, Mg, Be, C, and the like.

### (Oxidation Confinement Layer)

The oxidation confinement layer 104 has a non-oxidized region 104a and an oxidized region 104b surrounding the non-oxidized region 104a. The non-oxidized region 104a includes a compound semiconductor (for example, AlGaAs, AlAs, or the like). The oxidized region 104b includes an insulator (for example, an oxide such as AlxOy). Because the oxidized region 104b has a higher resistance and a lower refractive index than those of the non-oxidized region 104a, the non-oxidized region 104a functions as a current/light passing region, and the oxidized region 104b functions as a current/light confinement region. The oxidation confinement layer 104 is preferably disposed at a position of a node of a standing wave generated in the resonator or in the vicinity thereof.

### (First Cladding Layer)

As an example, the first cladding layer 105 includes p-AlGaAs. The cladding layer is also referred to as a “spacer layer”.

### (Light Emitting Layer)

As an example, the light emitting layer 106 includes a compound semiconductor having band gap energy smaller than those of the first and second semiconductor structures SS1 and SS2. As an example, the light emitting layer 106 includes a GaAs-based compound semiconductor (for example, GaAs, AlGaAs, GaInAs, GaInAsN, or the like). The light emitting layer 106 may have a quantum well structure, a multiple quantum well structure, or a quantum dot structure. The light emitting layer 106 is also referred to as an “active layer”. The light emitting layer 106 includes a light emitting region which is a region (current injection region) into which electric current is injected in the light emitting layer 106 and is a region that emits light. The light emitting region is set by the oxidized region 104b of the oxidation confinement layer 104. The light emitting layer 106 is preferably disposed at a position of an antinode of the standing wave generated in the resonator or in the vicinity thereof.

### (Second Cladding Layer)

As an example, the second cladding layer 107 includes n-AlGaAs. The cladding layer is also referred to as a “spacer layer”.

### (Second Semiconductor Multilayer Film Reflector)

As an example, the second semiconductor multilayer film reflector 108 is a semiconductor multilayer film reflector doped with n-type impurities, has low light absorption, and has high reflectance and conductivity. The semiconductor multilayer film reflector has a structure in which a plurality of types (for example, two types) of semiconductor layers (for example, n-AlGaAs layers) having different refractive indexes is alternately laminated with an optical thickness of ¼ wavelength of the emission wavelength. Examples of the n-type impurities (dopant) include, for example, Si, Se, Ge, and the like. The second semiconductor multilayer film reflector 108 is set slightly higher in reflectance than the first semiconductor multilayer film reflector 103.

### (Second Contact Layer)

The second contact layer 109 is a semiconductor layer having high carrier conductivity and low resistance and, as an example, includes an n-GaAs layer highly doped with n-type impurities. Examples of the n-type impurities (dopant) include, for example, Si, Se, Ge, and the like. The contact layer is also referred to as a “current injection layer”.

### (Dummy Element Part, Spacer)

In the surface emitting device 10, a spacer SP is interposed between the peripheral region PA and the mounting substrate 200. More specifically, as an example, a dummy bump DB included in the spacer SP is interposed between the outermost peripheral portion of the peripheral region PA and the mounting substrate 200. Here, the spacer SP includes a plurality of the dummy bumps DB. More specifically, as an example, the dummy bump DB is interposed between the second region R2 of the dummy element part DE, which is the outermost peripheral portion of the peripheral region PA, and the mounting substrate 200.

The dummy bump DB may or may not bond the second region R2 to the mounting substrate 200. That is, the dummy bump DB may be sandwiched between the second region R2 and the mounting substrate 200, or a gap may be present between one of the second region R2 and the mounting substrate 200, and the dummy bump DB. In other words, there may be play between one of the second region R2 and the mounting substrate 200, and the spacer SP. The second region R2 of the dummy element part DE is also a stealth dicing region SDA (laser irradiation area) of stealth dicing performed in a manufacturing method of the surface emitting device 10 described later.

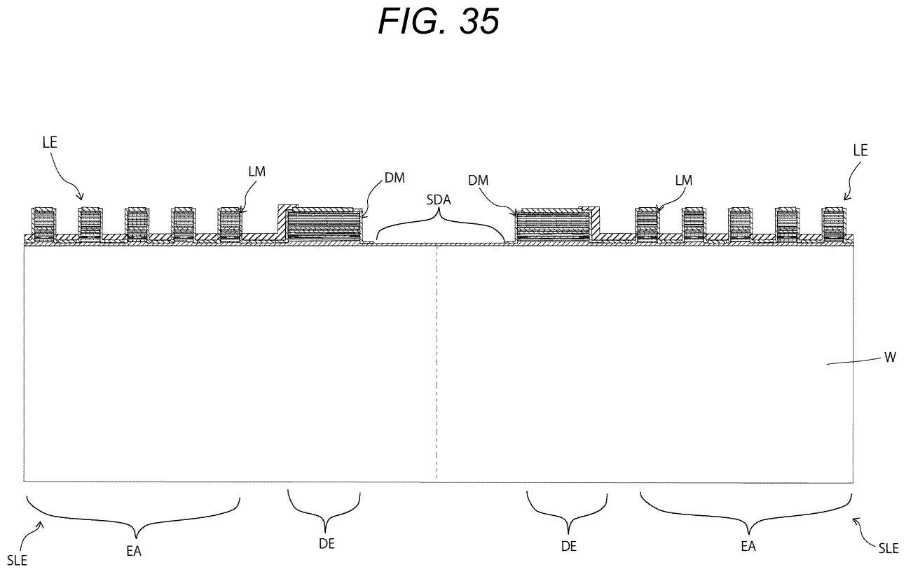

Incidentally, in recent years, miniaturization of the chip size of a chip-shaped surface emitting element (surface emitting chip) has progressed, and as a dicing method of a wafer on which a plurality of surface emitting elements is collectively formed, stealth dicing has come to be used in which chipping and cracks are not generated, processing debris is not generated, and a cutting margin is not generated. For example, as illustrated in a comparative reference view of FIG. 35, stealth dicing is a dicing method performed by condensing laser light in a laser irradiation area as the stealth dicing region SDA shared by adjacent surface emitting elements SLE on a wafer W and generating cracks in the wafer by thermal shock. For this reason, in the stealth dicing region SDA, a shielding object such as a metal that shields the laser light, a layer that absorbs the laser light to cause the light density of the focal point of the laser light to be reduced, unevenness that disturbs the optical path of the laser light, and the like have not been able to be provided. That is, the stealth dicing region SDA has been required to be a flat area having no structure that affects the laser light.

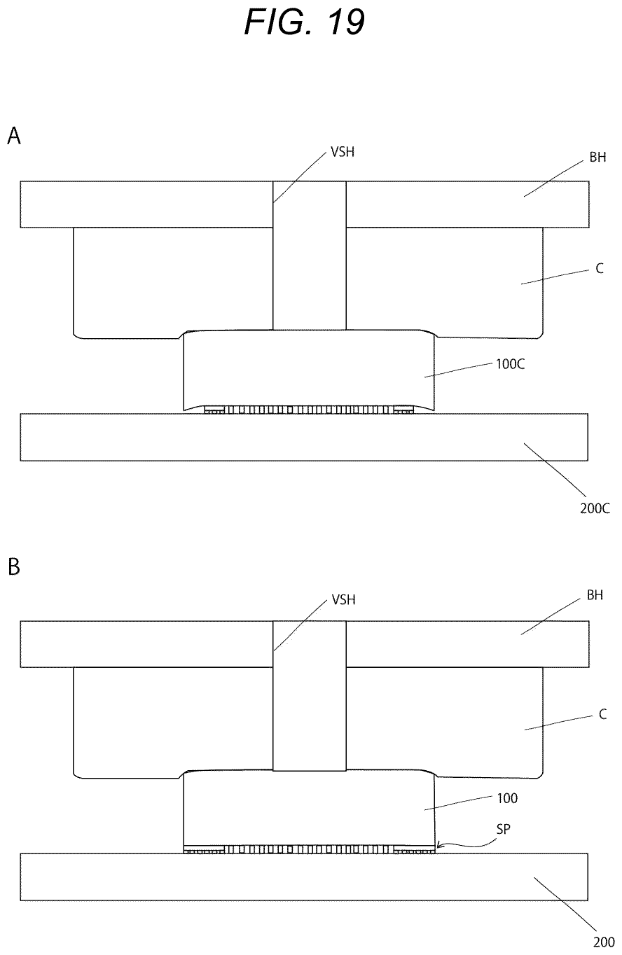

In the example of FIG. 35, a flat area without a Structure (the stealth dicing region SDA, the laser irradiation area) for stealth dicing is provided in the outer peripheral portion on the outer side of a bump bonding area (the element region EA and the dummy element part DE) of each of the two adjacent surface emitting elements SLE on the wafer W. The sum of the widths of the flat areas of the two surface emitting elements SLE whose flat areas are adjacent to each other necessary for the stealth dicing is about 0.4 times the thickness of the wafer W, and is, for example, 40 μm in a case where the thickness of the wafer W is 100 μm. Therefore, the width of the flat area required for the outer peripheral portion of one surface emitting element SLE is half of the total described above, that is, about 0.2 times the thickness of the wafer W. As long as the thickness of the wafer W does not change, the required width of the flat area does not change, and thus, the proportion of the flat area in the surface emitting chip (chip-shaped surface emitting element) increases as the miniaturization of the chip size progresses. As the miniaturization of the chip size further progresses, the ratio of the flat area of the chip outer peripheral portion where no structure is provided increases, and at the time when the surface emitting chip is press-bonded to the mounting substrate, the chip outer peripheral portion without a structure is strongly pushed, which causes the surface emitting chip to be easily deflected (see FIG. 19A). When the surface emitting chip is deflected at the time of press bonding, the deflected surface emitting chip exerts a return force (reaction force) after bonding, a strong tensile stress is applied to the light emitting element part LE and the electrode in the vicinity of the chip outer peripheral portion, and there is a concern that the surface emitting chip is damaged or reliability is lowered.

Therefore, in the surface emitting device 10, the spacer SP is constituted of the plurality of dummy bumps DB (structures) that can be easily formed in the stealth dicing region SDA (flat area) after the stealth dicing.

The dummy bump DB can be formed simultaneously in parallel with the first and second bumps B1 and B2 at the time of performing the bump bonding of the surface emitting element 100 to the mounting substrate 200.

As an example, the second region R2 of the dummy element part DE extends along at least a part (for example, the entire circumference) of the outer periphery of the element region EA (see FIG. 3).

The spacer SP is provided along at least a part (for example, the whole) of the second region R2 in the extending direction (circumferential direction). More specifically, the spacer SP includes a plurality of dummy bump groups aligned in the extending direction (circumferential direction) of the second region R2. Each dummy bump group includes a plurality of (for example, three) the dummy bumps DB aligned in a direction intersecting (for example, orthogonal to) the extending direction.

An emission surface, which is a surface of the surface emitting element 100 on the opposite side to the mounting substrate 200 side (the back surface (upper surface) of the substrate 101), is a flat surface. A surface (lower surface) of the dummy element part DE on the mounting substrate 200 side is a flat surface. An insulating film or a transparent conductive film transparent to the wavelength of laser light used for stealth dicing may be provided on the flat surface. The presence of these flat surfaces can be a proof that the surface emitting element 100 has been singulated by stealth dicing.

At least one modified layer (for example, first and second modified layers SD1 and SD2) can be present on the side surface of the substrate 101 in the outermost peripheral portion of the peripheral region PA (the second region R2 of the dummy element part DE). The presence of the modified layer can be a proof that the surface emitting element 100 has been singulated by stealth dicing. As an example, the oxidized region is not provided on the side surface of the oxidation confinement layer 104 in the outermost peripheral portion of the peripheral region PA (the second region R2 of the dummy element part DE).

In the direction (laminating direction) orthogonal to the in-plane direction, the surface (former) of the second region R2 of the dummy element part DE on the mounting substrate 200 side and the surface (latter) of the cathode electrode 115 on the mounting substrate 200 side are at the same position. This means that a load can be uniformly applied to the surface emitting element 100 at the time of flip-chip mounting (bump mounting) of the surface emitting element 100 on the mounting substrate 200 (the interval between the substrate 101 and the mounting substrate 200 can be made uniform in the plane), and element damage due to bonding failure or local stress can be suppressed. However, strictly, there is a slight difference between the positions in the laminating direction of the former and the latter.

Specifically, as an example, in the direction orthogonal to the in-plane direction, the surface (lower surface) of the cathode electrode 115 on the mounting substrate 200 side is located closer to the mounting substrate 200 by, for example, a predetermined distance (minute distance) than the surface (lower surface) of the second region R2 of the dummy element part DE on the mounting substrate 200 side. The thickness of the spacer SP (the thickness of each dummy bump DB) is thicker than the thickness of the first bump B1, for example, by the predetermined distance, and is thicker than the thickness of the second bump B2, for example, by the thickness of the anode electrode 112. With this arrangement, the distance between the substrate 101 and the mounting substrate 200 can be made more uniform in the plane. Note that, for example, in a case where the positional relationship between the two surfaces in the direction orthogonal to the in-plane direction is reversed, the thickness of the spacer SP is preferably smaller than the thickness of the first bump B1 and larger than the thickness of the second bump B2.

### (Bump)

As illustrated in FIG. 3, as an example, the plurality of first bumps B1 is arranged in a matrix correspondingly to the plurality of light emitting element parts LE. As an example, the plurality of second bumps B2 is arranged in a matrix correspondingly to the first region R1 of the dummy element part DE. As an example, the plurality of dummy bumps DB is arranged in a matrix correspondingly to each side of the second region R2 of the dummy element part DE.

As an example, the first bump B1, the second bump B2, and the dummy bump DB each include a material that is not easily crushed by pressurization. Moreover, as an example, the first bump B1, the second bump B2, and the dummy bump DB include the same conductive material. Note that the dummy bump DB may include, for example, a conductive resin, a semi-insulating resin, an insulating resin, or the like.

The conductive material constituting the first bump B1, the second bump B2, and the dummy bump DB is preferably a conductive material that can be transitioned from a softened state (relatively soft state) to a cured state (relatively hard state) at the time of bump bonding. Specifically, the conductive material contains a material that is not easily crushed by pressurization.

More specifically, the conductive material may be, for example, a metal particle paste. The metal particle paste can be gradually transitioned from a softened state to a cured state by pressurization. Moreover, the metal paste can be solidified by sintering. Examples of the metal particle paste include, for example, an Au particle paste, an Ag particle paste, and a Cu particle paste, and the like.

The metal particle paste is preferably a metal nano paste containing metal nanoparticles. In the metal nano paste, metal particles containing metal nanoparticles having a particle size of less than 1 μm are dispersed in a resin binder. Examples of the metal nano paste include, for example, an Au nano paste, an Ag nano paste, and a Cu nano paste, and the like.

The conductive material may be, for example, an alloy paste. The alloy paste may be, for example, a solder paste (cream solder). The solder paste has properties (thixotropy) in which the viscosity decreases (softens) by being stirred and returns to the original state (cured state) by being left to stand. Specific examples of the solder paste include, for example, those of an Sn-Ag based, Sn-Au based, Sn-Cu based, and the like.

As an example, it is preferable that the difference in the in-plane arrangement density (area density) of the first bumps B1, the second bumps B2, and the dummy bumps DB is as small as possible (ideally, 0). With this arrangement, the load applied to the surface emitting element 100 at the time of mounting the surface emitting element 100 on the mounting substrate 200 (at the time of bump bonding) can be made more uniform in the plane, and the deformation of the surface emitting element 100 can be further suppressed.

### (Mounting Substrate)

The mounting substrate 200 includes a semiconductor substrate 201 as a substrate part, a first electrode 202 (negative electrode) joined to each cathode electrode 115 with the first bump B1 interposed therebetween, and a second electrode 203 (positive electrode) joined to the anode electrode 112 while interposing the second bump B2 therebetween.

The driver included in the drive substrate serving as the mounting substrate 200 or the driver connected to the wiring substrate serving as the mounting substrate 200 includes, as an example, a power supply and a transistor (for example, an n-metal oxide semiconductor field efect transistor (MOSFET), a p-MOSFET, or the like) that controls on/off of energization from the power supply to the surface emitting element 100.

### <<Operation of Surface Emitting Device>>

Hereinafter, the operation of the surface emitting device 10 will be described. When the power supply voltage of the driver is applied to the surface emitting element 100, an electric current from the anode side of the driver is injected into the first contact layer 102 via the second electrode 203, the second bump B2, the anode electrode 112, the wiring 114, and the intermediate electrode 113. The electric current that has passed through the first contact layer 102 flows into the first semiconductor multilayer film reflector 103 of each light emitting element part LE, is confined by the oxidation confinement layer 104, and is injected into the light emitting region of the light emitting layer 106 through the first cladding layer 105. At this time, the light emitting region emits light, and the light travels between the first and second semiconductor multilayer film reflectors 103 and 108 while being confined by the oxidation confinement layer 104 and amplified by the light emitting layer 106, and is emitted as laser light from the back surface side (upper surface side) of the substrate 101 when the oscillation condition is satisfied. The electric current injected into the light emitting region flows out to the cathode side of the driver through the second cladding layer 107, the second semiconductor multilayer film reflector 108, the second contact layer 109, the cathode electrode 115, the first bump B1, and the first electrode 202 in this order.

### <<Manufacturing Method of Surface Emitting Device>>

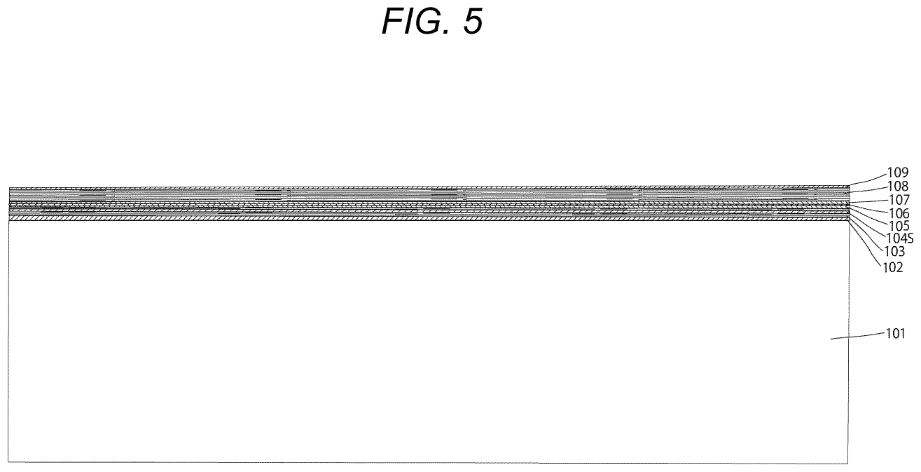

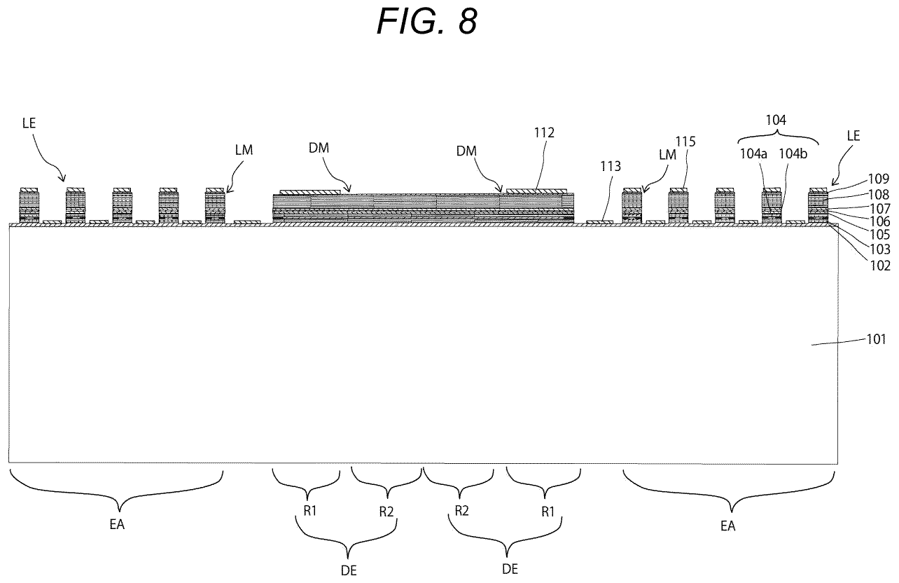

Hereinafter, an example of the manufacturing method of the surface emitting device 10 will be described with reference to the flowchart in FIG. 8 and process diagrams (FIGS. 5 to 18) of the manufacturing method of the surface emitting device 10. As an overall flow, first, a plurality of the surface emitting elements 100 is simultaneously generated on one wafer (hereinafter, referred to as the “substrate 101” for convenience) which is a base material of the substrate 101 by a semiconductor manufacturing method using a semiconductor manufacturing device. Next, the plurality of continuous integrated surface emitting elements 100 is separated from each other by dicing to obtain the chip-shaped surface emitting elements 100 (surface emitting chips).

The chip-shaped surface emitting element 100 is mounted on the mounting substrate 200.

In the first step S1, a laminate is generated (see FIG. 5). Specifically, for example, by using an epitaxial crystal growth method such as a metal organic chemical vapor deposition (MOCVD) method, the first contact layer 102, the first semiconductor multilayer film reflector 103 having an oxidation target layer 104S (for example, an AlGaAs layer, an AlAs layer, or the like) disposed therein, the first cladding layer 105, the light emitting layer 106, the second cladding layer 107, the second semiconductor multilayer film reflector 108, and the second contact layer 109 are laminated in this order on the substrate 101 as a growth substrate to generate the laminate. At this time, as raw materials of the compound semiconductor, for example, a methyl-based organometallic gas such as trimethylaluminum (TMAl), trimethylgallium (TMGa), or trimethylindium (TMIn) and an arsine (AsH3) gas are used, as raw materials of donor impurities, for example, disilane (Si2H6) is used, and as raw materials of acceptor impurities, for example, carbon tetrabromide (CBr4) is used.

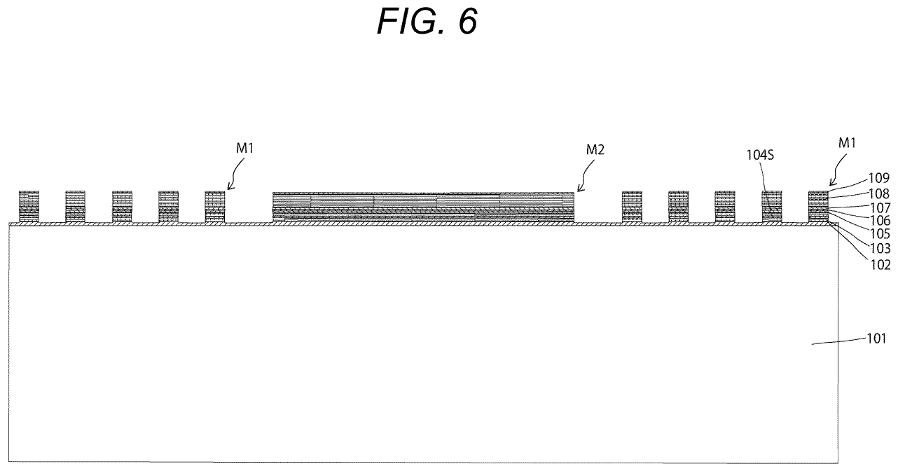

In the next step S2, a first mesa M1 to be the light emitting mesa LM and a second mesa M2 to be the integrated two dummy mesas DM (two adjacent dummy mesas DM) are formed (see FIG. 6). Specifically, a resist pattern covering a portion where the first and second mesas M1 and M2 are to be formed is formed on the laminate by photolithography, and the laminate is etched by dry etching or wet etching by using the resist pattern as a mask. The etching at this time is performed, for example, until the etching bottom surface reaches the inside of the first contact layer 102. As a result, the first and second mesas M1 and M2 are formed. Thereafter, the resist pattern is removed. Note that an etching stop layer (for example, an InGaP layer) may be disposed between the first contact layer 102 and the first semiconductor multilayer film reflector 103.

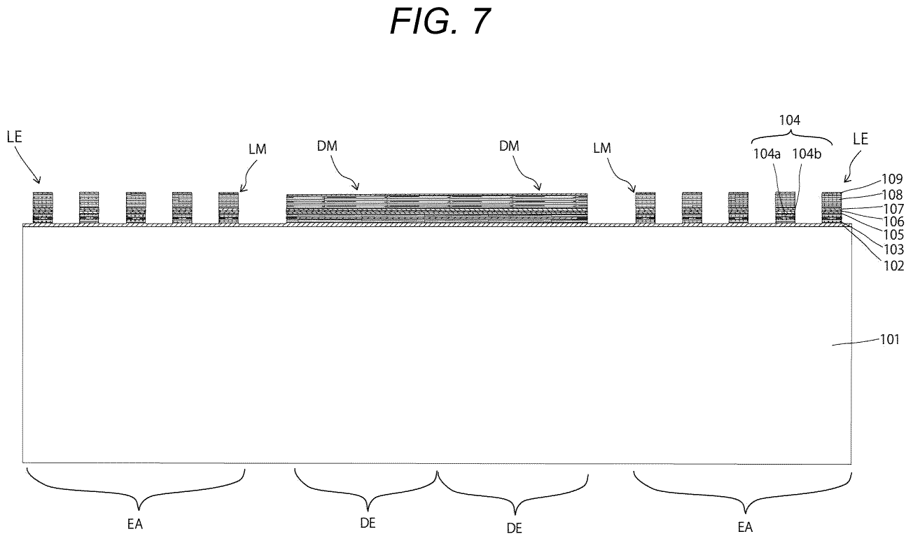

In the next step S3, the oxidation confinement layer 104 is formed (see FIG. 7). Specifically, the first and second mesas M1 and M2 (see FIG. 6) are exposed to a high-temperature water vapor atmosphere, and the oxidation target layer 104S is selectively oxidized by a predetermined distance from the side surface. As a result, the oxidation confinement layer 104 in which the non-oxidized region 104a is surrounded by the oxidized region 104b is formed in the first mesa M1, and the light emitting mesa LM is generated. A layer in which the non-oxidized region is surrounded by the oxidized region is also formed in the second mesa M2, and two integrated dummy mesas DM are generated.

In the next step S4, the anode electrode 112, the intermediate electrode 113, and the cathode electrode 115 are formed (see FIG. 8). Specifically, for example, by a lift-off method, the cathode electrode 115 is formed in a solid form on the top portion of the light emitting mesa LM, the anode electrode 112 is formed in a solid form on the top portion of the dummy mesa DM, and the intermediate electrode 113 covering a region between the mesas on the upper surface of the first contact layer 102 is formed. At this time, for example, vapor deposition, sputtering, or the like is used for forming the electrode material.

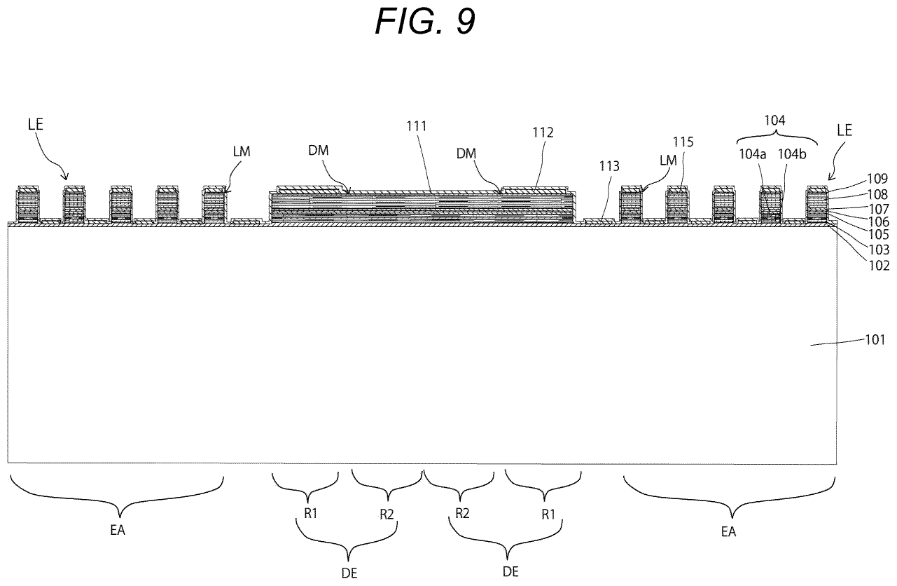

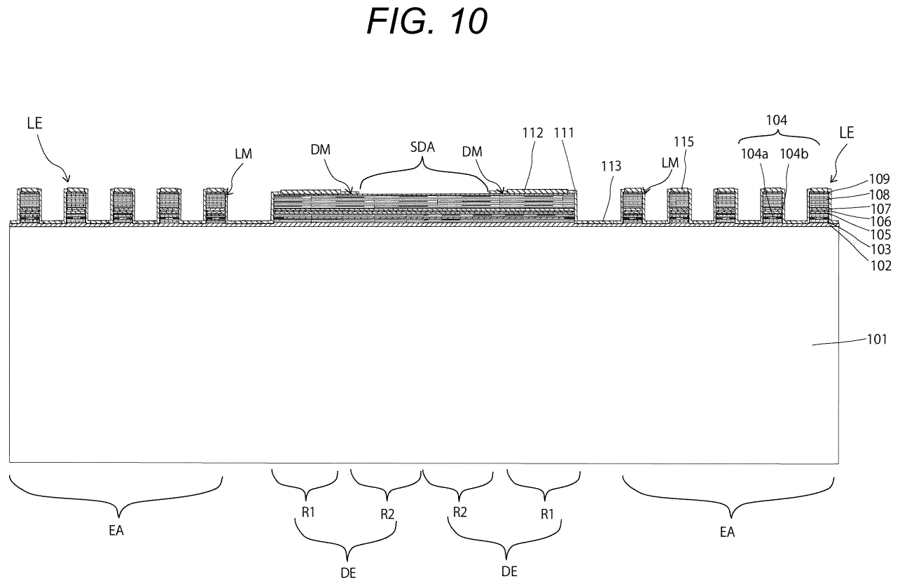

In the next step S5, the insulating film 111 is formed. Specifically, first, the insulating film 111 is formed on the entire surface (see FIG. 9). Next, a part of the insulating film 111 is removed by photolithography and etching to expose the anode electrode 112, the intermediate electrode 113, the cathode electrode 115, and the stealth dicing region SDA of the integrated two dummy mesas DM (see FIG. 10).

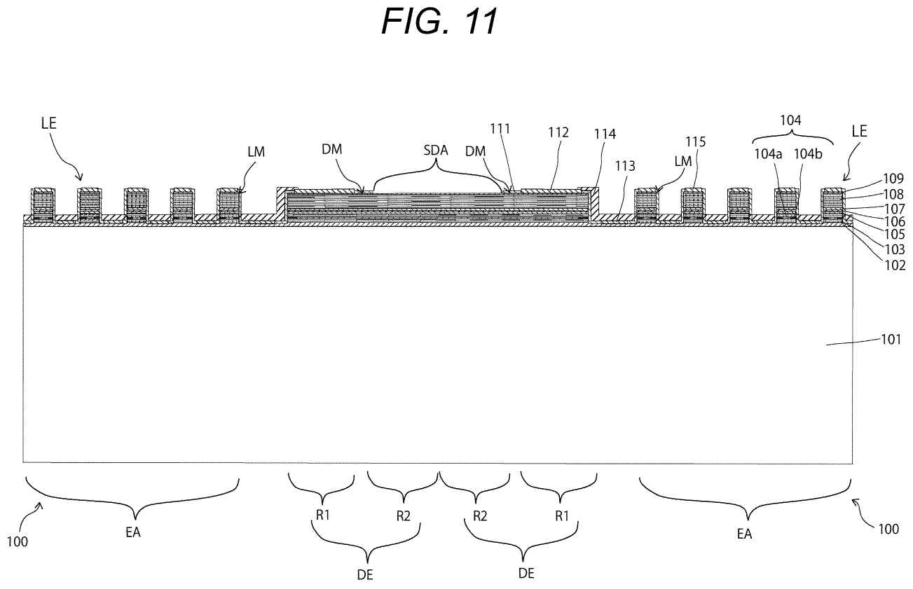

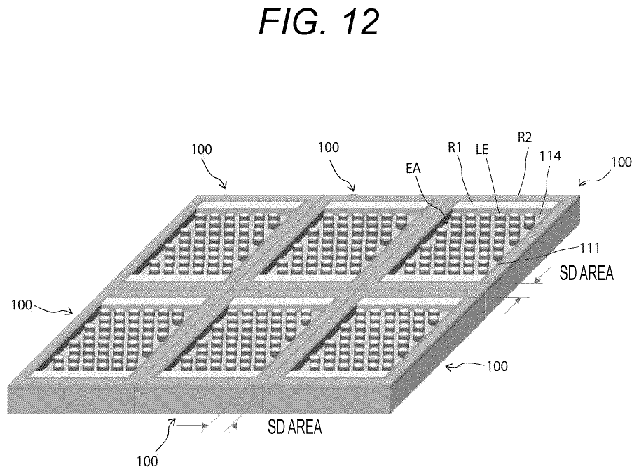

In the next step S6, the wiring 114 is formed (see FIGS. 11 and 12). Specifically, for example, the wiring 114 is formed by a plating method such that the wiring 114 covers the intermediate electrode 113, the insulating film 111 formed on the outer peripheral portion of the side surfaces and the upper surface of the integrated two dummy mesas DM, and the outer peripheral portion of the anode electrode 112. Note that, prior to the plating method, a seed layer is preferably formed in advance at a portion to be plated.

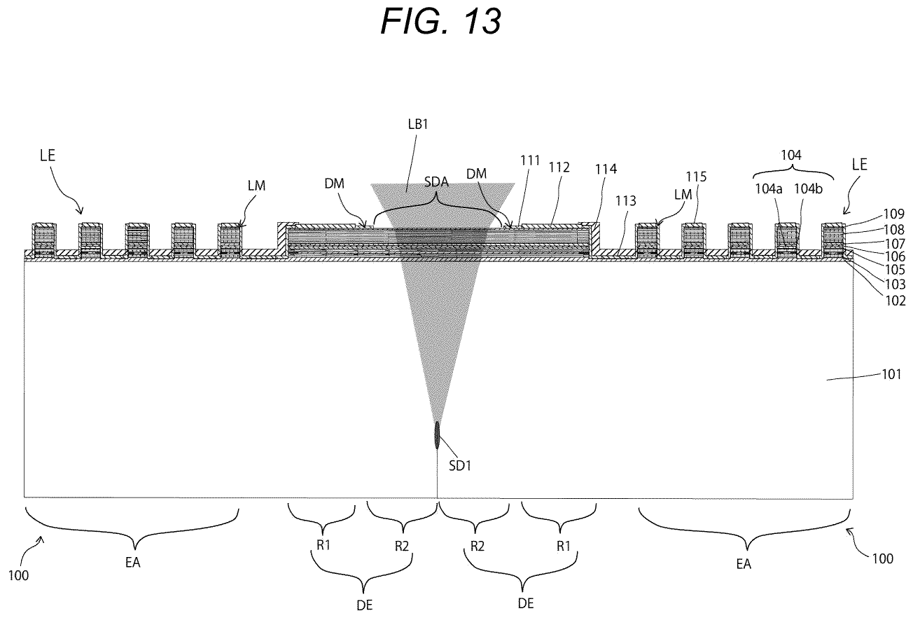

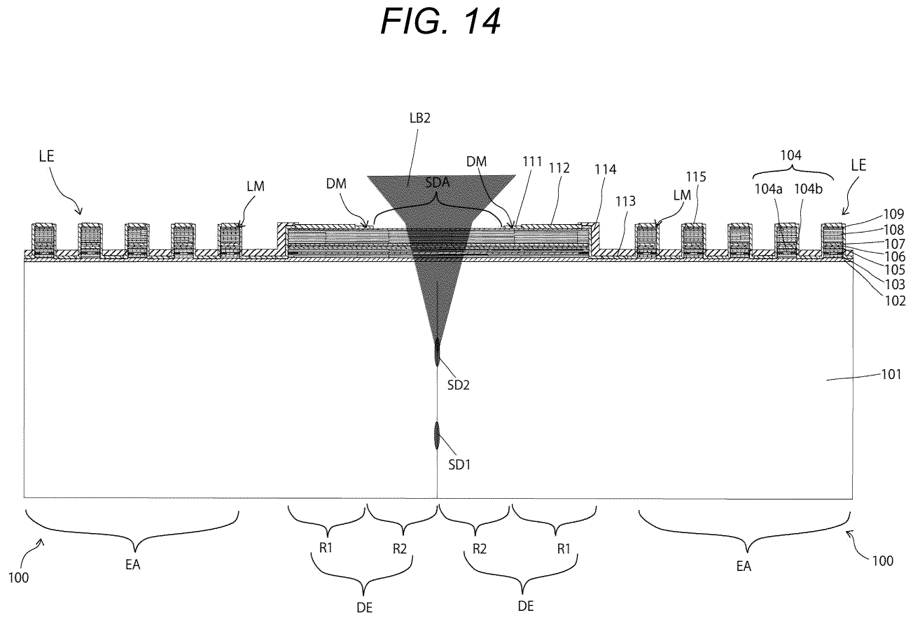

In the next step S7, stealth dicing is performed (see FIGS. 13 and 14). Prior to the stealth dicing, it is preferable to polish the back surface of the substrate 101 with a back glider or a chemical mechanical polisher (CMP) device to thin the substrate 101 to, for example, about 100 μm. As an example, the stealth dicing is performed, in a state where the substrate 101 is attached with a dicing tape on the back surface (lower surface) thereof to be tape-mounted, by scanning the stealth dicing region SDA (flat area) from the front surface (upper surface) side of the substrate 101 in the extending direction (circumferential direction) of the second region R2 along the boundary between the adjacent dummy element parts DE while controlling the focusing of the laser light.

The focus control here is control in which the focal point of the laser light is positioned at a first depth position (a position closer to the back surface of the substrate 101) in the substrate 101 and then positioned at a second depth position (a position farther from the back surface of the substrate 101 than the first depth position) in the substrate 101 at each scanning position. When the focal point of the laser light is at the first depth position, multiphoton absorption occurs at a high light density, heat is rapidly generated, and the thermal shock caused thereby generates the first modified layer SD1 and a crack in the substrate 101, the crack extending from the first modified layer SD1 as a starting point to the back surface of the substrate 101 (see FIG. 13). When the focal point of the laser light is at the second depth position, multiphoton absorption occurs at a high light density, heat is rapidly generated, and the thermal shock caused thereby generates the second modified layer SD2 and a crack in the substrate 101, the crack extending to the back surface side of the substrate 101 from the second modified layer SD2 as a starting point and extending to the first modified layer SD1 (see FIG. 14).

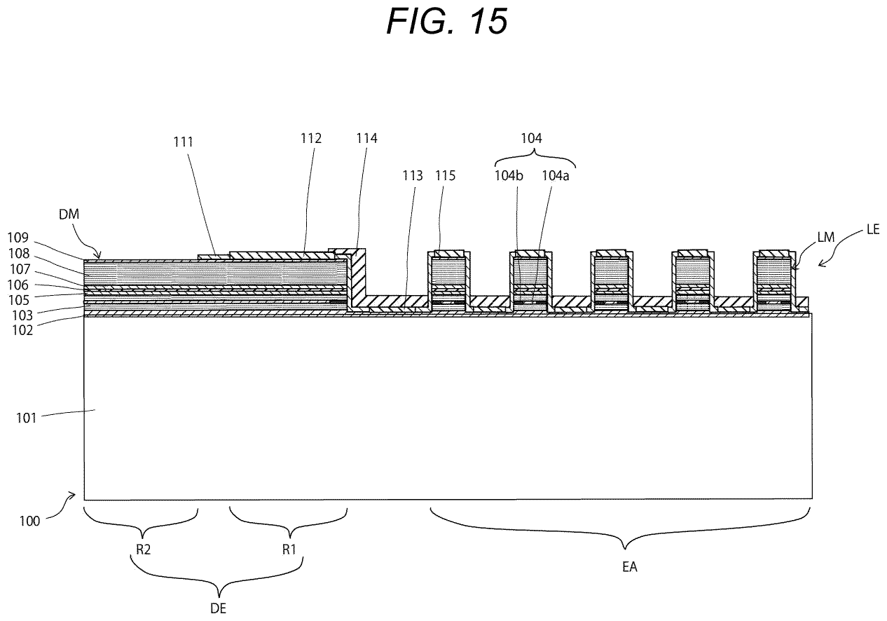

Thereafter, the tape-mounted substrate 101 is applied to a tape drawing machine to cause the plurality of surface emitting elements 100 to be divided into chip shapes, and the dicing is completed (see FIG. 15).

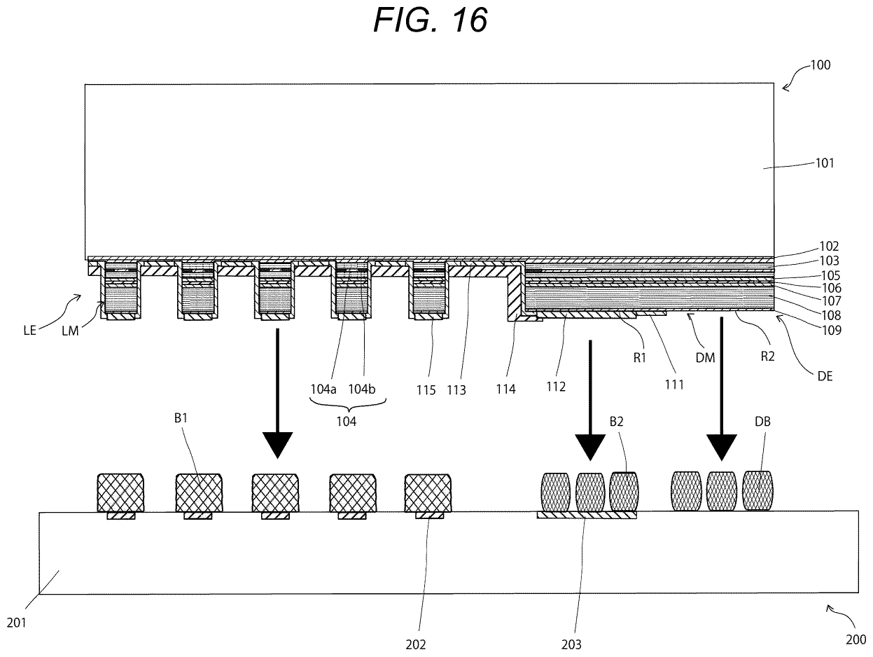

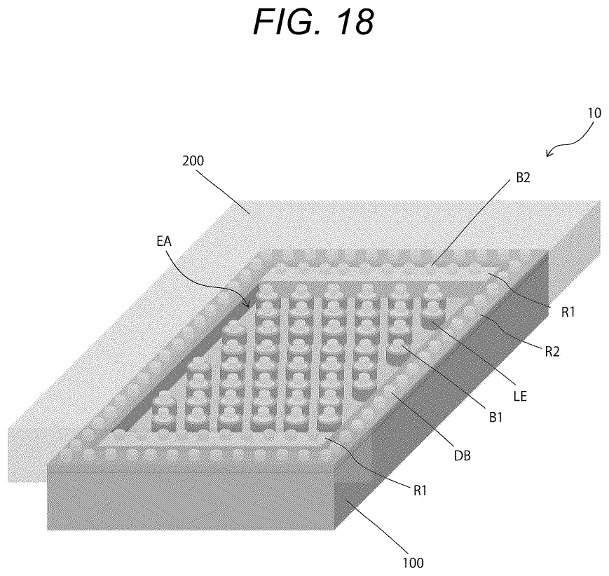

In the final step S8, the surface emitting element 100 is mounted (flip-chip mounted) on the mounting substrate 200 (see FIGS. 16 to 18, where FIG. 18 is a schematic view illustrating a state in which the mounting substrate 200 is seen through). Specifically, first, the first bumps B1 in the softened state are each attached onto each of the first electrodes 202 of the mounting substrate 200, the second bumps B2 in the softened state are attached to the second electrode 203, and the dummy bumps DB in the softened state are attached to a portion corresponding to the second region R2 of the dummy element part DE (see FIG. 16). Here, the arrangement density (area density) and the size of each bump may be set such that the difference in the amount of collapse of the bump at the time when a predetermined pressure is applied to the bump becomes small to cause the interval between the substrate 101 and the mounting substrate 200 to become substantially constant in the plane. Here, each bump contains a conductive material that is not easily crushed by pressurization. For example, in a case where each bump is a solder paste, the bump is previously stirred in the cured state to become the softened state.

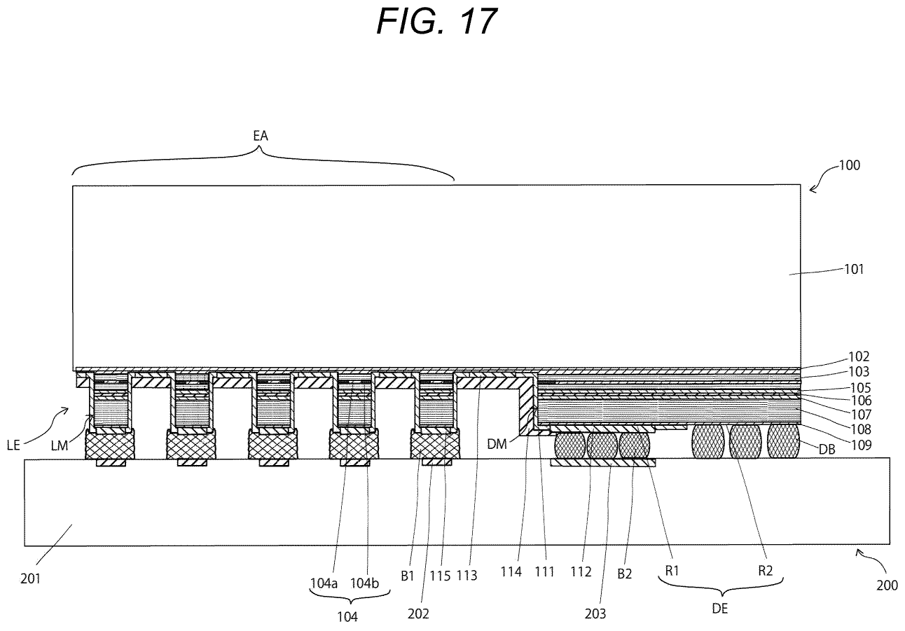

Next, the chip-shaped surface emitting element 100 is vacuum-sucked and picked up on the back surface of the substrate 101 by a bonding head BH with a collet C (buffer material) through which a vacuum suction hole VSH penetrates, for example, as illustrated in FIG. 19B, and is aligned with respect to the mounting substrate 200 such that the cathode electrode 115 and the first bump B1 face each other, the anode electrode 112 and the second bump B2 face each other, and the second region R2 and the dummy bump DB face each other (see FIG. 16). Thereafter, pressure bonding is performed in a high-temperature environment. At this time, the entire surface emitting element 100 is uniformly pressed against the mounting substrate 200 at a predetermined pressure, the cathode electrode 115 and the first electrode 202 are bonded with the first bump B1 interposed therebetween, and the anode electrode 112 and the second electrode 203 are bonded with the second bumps B2 interposed therebetween (see FIGS. 17 and 18). At this time, because the plurality of dummy bumps DB is interposed as spacers in a gap between the second region R2 and the mounting substrate 200, the deflection of the surface emitting element 100 is suppressed (see FIG. 19B). Moreover, because the bump gradually transitions from the softened state to the cured state in the process of being crushed, the stress applied to the surface emitting element 100 is dispersed from the initial stage of bonding to the middle stage of bonding, and element breakage is suppressed. From the middle stage of bonding to the final stage of bonding, each bump becomes relatively hard so that the sufficient bonding strength (bonding rigidity) can be obtained. On the other hand, for example, as in the comparative example illustrated in FIG. 19A, in a case where a spacer is not interposed between the outermost peripheral portion of a surface emitting element 100C and a mounting substrate 200C at the time of bump bonding, the surface emitting element 100C is deflected, and a tensile stress is applied to the surface emitting element 100C after bonding, which causes concerns that the element is damaged or reliability is lowered.

Next, each bump is solidified. Specifically, for example, in a case where each bump is a metal particle paste, the bump may be heated while being pressurized to be sintered and solidified, or may be sintered in a heating furnace to be solidified (by reflow). For example, in a case where each bump is a solder paste, the bump is solidified by being left for a predetermined time from the end of stirring.

Note that, because the dummy bump DB is not sandwiched between the metals, the dummy bump DB is easily peeled off, and there is a possibility that the dummy bump DB falls off after bump bonding, but there is no particular problem. This is because the dummy bump DB functioning as a spacer is important at the time of bump bonding in which the entire surface emitting element 100 is pressed against the mounting substrate 200, and is not so important after the bump bonding.

After the bump bonding, an underfill may be injected (preferably filled) into the gap between the surface emitting element 100 and the mounting substrate 200 in order to protect the bonding portion from foreign substances and the like and to improve the bonding strength.

In the focus control described above, the focal point of the laser light is controlled at two depth positions. However, for example, the focal point may be controlled at one depth position in a case where the wafer is thinner, or may be controlled at three or more depth positions in a case where the wafer is thicker.

### <<Effects of Surface Emitting Device and Manufacturing Method of Surface Emitting Device>>

Hereinafter, effects of the surface emitting device 10 and the manufacturing method of the surface emitting device 10 will be described.

The surface emitting device 10 includes the surface emitting element 100 including the element region EA and the peripheral region PA of the element region EA, and the mounting substrate 200 on which the surface emitting element 100 is mounted. The element region EA has the light emitting element part LE provided with the cathode electrode 115 on the mounting substrate 200 side, the cathode electrode 115 is bonded to the mounting substrate 200 with the first bump B1 interposed therebetween, and the spacer SP is interposed between the peripheral region PA and the mounting substrate 200.

In the surface emitting device 10, the cathode electrode 115 provided in the light emitting element part LE and the mounting substrate 200 can be bonded together with the first bump B1 interposed therebetween, while having the spacer SP interposed between the peripheral region PA and the mounting substrate 200 at the time when the surface emitting element 100 is mounted on the mounting substrate 200 (at the time of performing bump bonding).

As a result, according to the surface emitting device 10, there can be provided the surface emitting device that can suppress deformation (elastic deformation) (deflection) of the surface emitting element 100 at the time of mounting the surface emitting element 100 on the mounting substrate 200.

On the other hand, in the semiconductor device described in Patent Document 1, in order to make the gap between the plurality of electrodes of the opposed chips constant, a height adjustment pad is provided in some electrodes to mechanically make the gap constant. However, when this configuration is applied to the surface emitting device, the surface emitting chip deflects concavely due to pressing at the time of bonding, and a strong stress is applied particularly to the light emitting element part in the vicinity of the adjustment pad, which causes a concern of the surface emitting chip being damaged or reliability being lowered.

In the mounting structure of the semiconductor element described in Patent Document 2, the connection bumps at four corners of the semiconductor element are densified to reduce bump cracks caused by heat stress at the connection portions, the heat stress occurring by heat generated at the time of driving the element. However, when this configuration is applied to the surface emitting device, the surface emitting element deflects concavely due to pressing at the time of bump bonding, and a strong stress is applied particularly to the light emitting element part in the vicinity of the connection bumps at four corners, which causes a concern of the surface emitting element being damaged or reliability being lowered.

The spacer SP is interposed between the outermost peripheral portion of the peripheral region PA and the mounting substrate 200. With this arrangement, deformation of the surface emitting element 100 at the time of bump bonding can be more effectively suppressed.

The peripheral region PA has the dummy element part including the outermost peripheral portion. With this arrangement, the thickness of the spacer SP can be thinned.

The outermost peripheral portion of the peripheral region PA extends along at least a part (for example, the entire circumference) of the outer periphery of the element region EA, and the spacer SP is provided along at least a part (for example, the entire circumference) in the extending direction of the outermost peripheral portion of the peripheral region PA. With this arrangement, a range in which deformation of the surface emitting element 100 can be suppressed at the time of bump bonding can be extended in the circumferential direction of the outermost peripheral portion.

The outermost peripheral portion of the peripheral region PA extends along the entire circumference of the outer periphery of the element region EA. With this arrangement, the spacer SP can be provided along the entire circumference of the outermost peripheral portion of the peripheral region PA. In this case, deformation can be suppressed in the entire circumference of the surface emitting element 100 at the time of bump bonding.

The spacer SP has a plurality of portions aligned in the extending direction of the outermost peripheral portion of the peripheral region PA. With this arrangement, the spacer SP can be constituted of a plurality of structures.

The spacer SP includes the dummy bump DB. With this arrangement, the spacer SP can be formed at the time of bump bonding. For example, because a structure to be the spacer SP does not need to be formed before the surface emitting element 100 is diced by stealth dicing, stealth dicing can be accurately performed, and chipping and cracking are less likely to occur in the surface emitting element 100. Because the structure (the plurality of dummy bumps DB) to be the spacer SP can be formed after the surface emitting element 100 is diced by stealth dicing, deflection of the surface emitting element 100 at the time of bump bonding can be suppressed, and thus, breakage such as chip breakage and chip chipping can be suppressed, and element breakage and lowering in reliability due to strong tensile stress applied to the light emitting element part and the electrode in the vicinity of the outermost peripheral portion due to the deflection can also be suppressed. Therefore, a surface emitting element having high quality and high reliability can be provided.

The dummy bump DB is preferably provided on the dummy element part DE, and the surface of the dummy element part DE on the mounting substrate 200 side and the surface of the anode electrode 112 on the mounting substrate 200 side are preferably located on the same plane. With this arrangement, the thickness of the dummy bump DB and the thickness of the first bump B1 can be made the same.

Because the dummy bump DB can be formed simultaneously in parallel with the first bump Bl, variations in bump shape can be suppressed, an increase in the number of manufacturing steps can be suppressed, and the quality can be improved and the cost can be reduced.

The emission surface, which is the surface of the surface emitting element 100 on the opposite side to the mounting substrate 200 side is preferably a flat surface. With this arrangement, the quality of the emission surface can be improved.

The first and second modified layers SD1 and SD2 can be present on the side surface of the surface emitting element 100. With this arrangement, it can be estimated that the surface emitting element 100 has been diced by stealth dicing, and it can be ensured that element breakage and lowering in reliability are sufficiently suppressed as compared with a surface emitting element diced by, for example, a mechanical dicing method such as blade dicing.

In the direction orthogonal to the in-plane direction, the surface of the cathode electrode 115 on the mounting substrate 200 side may be located closer to the mounting substrate 200 than the surface of the outermost peripheral portion of the peripheral region PA on the mounting substrate 200 side, and the thickness of the spacer SP may be thicker than the thickness of the first bump B1.

The anode electrode 112 is provided on the mounting substrate 200 side of the dummy element part DE included in the peripheral region PA, and the anode electrode 112 is bonded to the mounting substrate 200 with the second bump B2 interposed therebetween. With this arrangement, bump bonding of the cathode electrode 115 and the anode electrode 112 to the mounting substrate 200 can be performed simultaneously, and the number of manufacturing steps can be reduced.

The element region EA has the plurality of light emitting element parts LE separated from each other in the in-plane direction, and the anode electrode 112 is a common electrode provided in common for the plurality of light emitting element parts LE. With this arrangement, the plurality of light emitting element parts LE can be independently driven while having the number of electrodes reduced.

The first bump B1 and the dummy bump DB each preferably include a material that is not easily crushed by pressurization. With this arrangement, element breakage during bump bonding can be suppressed and the bonding strength (bonding rigidity) can be improved.

The first bump B1 and the dummy bump DB include the same conductive material. With this arrangement, the bump bonding process can be facilitated and the cost can be reduced by limiting (reducing) the types of the bump material.

The peripheral region PA includes the dummy element part DE, and each of the light emitting element parts LE and the dummy element part DE includes the first and second semiconductor structures SS1 and SS2 laminated on each other, and the light emitting layer 106 disposed between the first and second semiconductor structures SS1 and SS2. With this arrangement, the surface emitting element 100 can be easily formed by the semiconductor manufacturing process.

The manufacturing method of the surface emitting device 10 includes a step of forming the surface emitting element 100 including the element region EA having the light emitting element part LE and the peripheral region PA of the element region EA, and a step of interposing the spacer SP between the peripheral region PA and the mounting substrate 200 and bonding the cathode electrode 115 provided on the light emitting element part LE and the mounting substrate 200 with the first bump B1 interposed therebetween.

According to the manufacturing method of the surface emitting device 10, the surface emitting device 10 can be manufactured while the surface emitting element 100 can be suppressed from being deformed (deflected) at the time of mounting the surface emitting element 100 on the mounting substrate 200.

In the manufacturing method of the surface emitting device 10, the spacer SP includes the dummy bump DB. With this arrangement, the spacer SP can be formed at the time of bump bonding.

The step of bonding described above is performed by pressing the emission surface, which is a surface of the surface emitting element 100 on the opposite side to the mounting substrate 200 side, toward the mounting substrate 200 side. With this arrangement, pressure bonding of the surface emitting element 100 to the mounting substrate 200 can be performed while the surface emitting element 100 is suppressed from being deformed. At this time, damage to the emission surface can be suppressed by pressing the emission surface toward the mounting substrate 200 side while interposing the cushioning material.

In the step of forming described above, the plurality of surface emitting elements 100 is collectively formed such that the peripheral regions PA are adjacent to each other, and after the step of forming and before the step of bonding described above, the manufacturing method includes a step of singulating the plurality of surface emitting elements 100 by stealth dicing. With this arrangement, there can be obtained the plurality of chip-shaped surface emitting elements 100 in which the emission surface is a high-quality flat surface and element breakage and lowering in reliability are suppressed.

### 2. Surface Emitting Device According to Example 2 of One Embodiment of the Present Technology

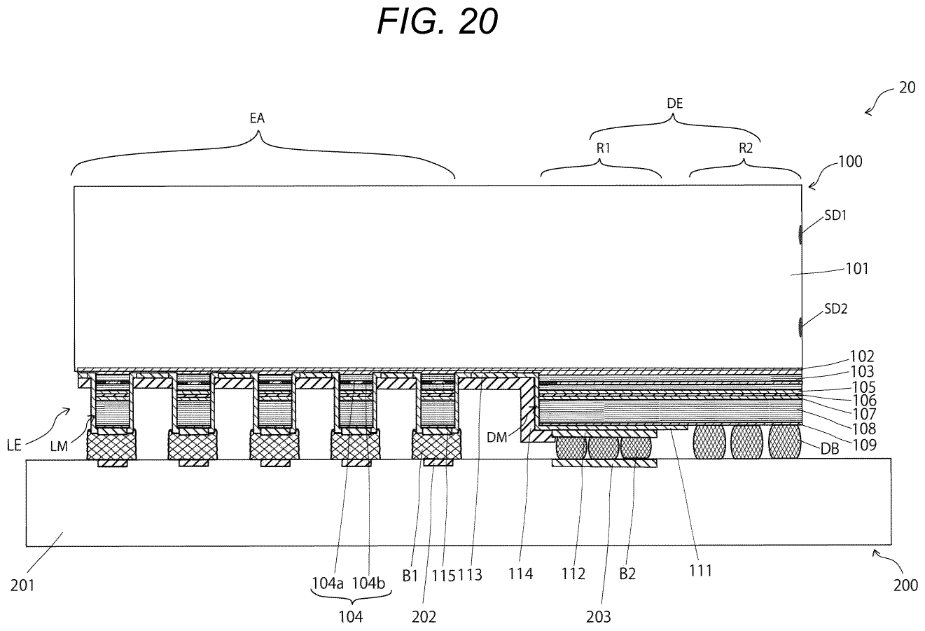

FIG. 20 is a cross-sectional view of a surface emitting device 20 according to Example 2 of one embodiment of the present technology.

As illustrated in FIG. 20, the surface emitting device 20 has a similar configuration to the surface emitting device 20 according to Example 1 except that the insulating film 111 is also disposed between the second contact layer 109 in the first region R1 of the dummy element part DE and the anode electrode 112. That is, the anode electrode 112 as a common electrode may be disposed on the second contact layer 109 as in the surface emitting device 10 according to Example 1, or may be disposed on the insulating film 111 as in the surface emitting device 20. The arrangement of the common electrode is preferably set according to inductance, conductance, and impedance design at the time of driving the surface emitting element 100.

### 3. Surface Emitting Device According to Example 3 of One Embodiment of the Present Technology

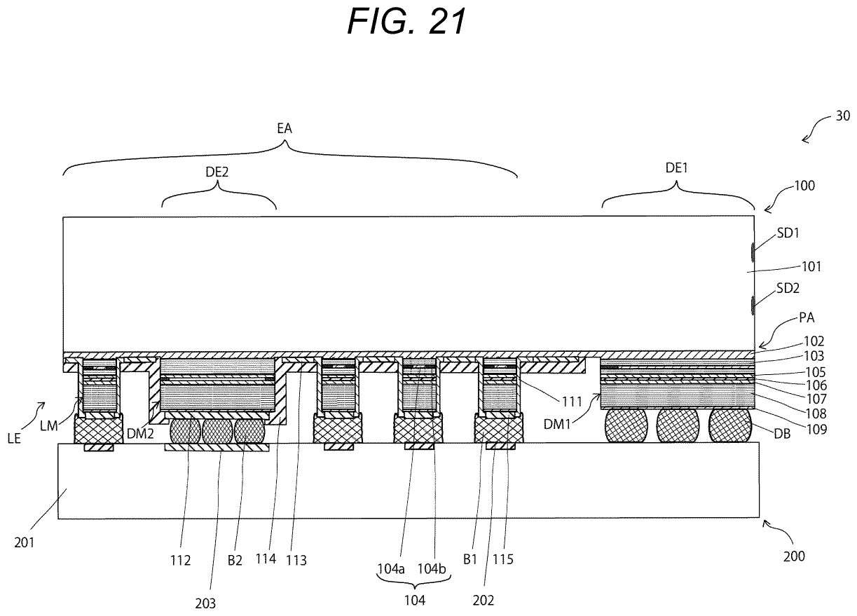

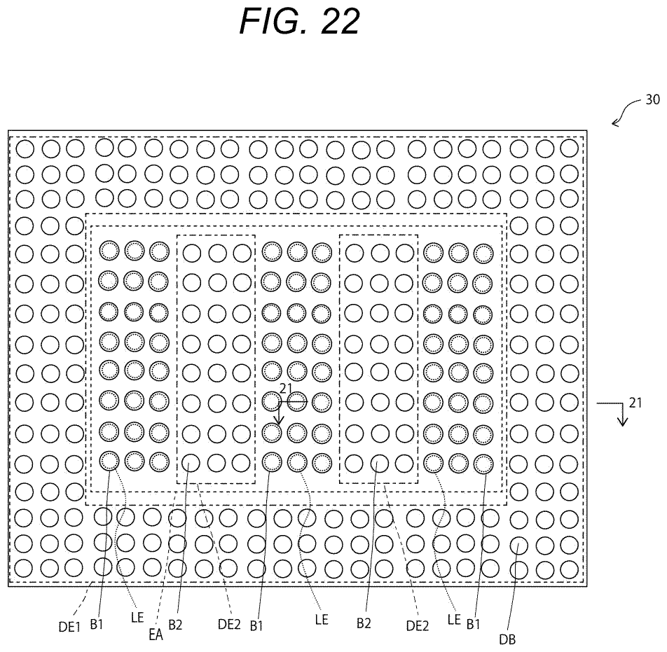

FIG. 21 is a cross-sectional view of a surface emitting device 30 according to Example 3 of one embodiment of the present technology. FIG. 22 is a bottom view of the surface emitting device 30 according to Example 3 of one embodiment of the present technology in a state where the mounting substrate 200 is omitted. FIG. 21 is a cross-sectional view taken along a line 21-21 in FIG. 22.

As illustrated in FIGS. 21 and 22, the surface emitting device 30 has a substantially similar configuration to the surface emitting device 10 according to Example 1 except that the peripheral region PA has a first dummy element part DE1 and the element region EA has at least one (for example, two) second dummy element parts DE2.

In the surface emitting device 30, the first dummy element part DE1 includes the outermost peripheral portion of the peripheral region PA, and has a first dummy mesa DM1 on the mounting substrate 200 side. The plurality of dummy bumps DB constituting a spacer is interposed between the first dummy mesa DM1 and the mounting substrate 200.

In the surface emitting device 30, as an example, the light emitting element part array includes a plurality of (for example, three) light emitting element part groups each including a plurality of (for example, 24) the light emitting element parts LE and a plurality of (for example, 3) the light emitting element part groups aligned in one direction (for example, the line 21-21 direction in FIG. 22) in the plane. The light emitting element part groups and the second dummy element parts DE2 are alternately aligned in the one direction described above.

### 4. Surface Emitting Device According to Example 4 of One Embodiment of the Present Technology

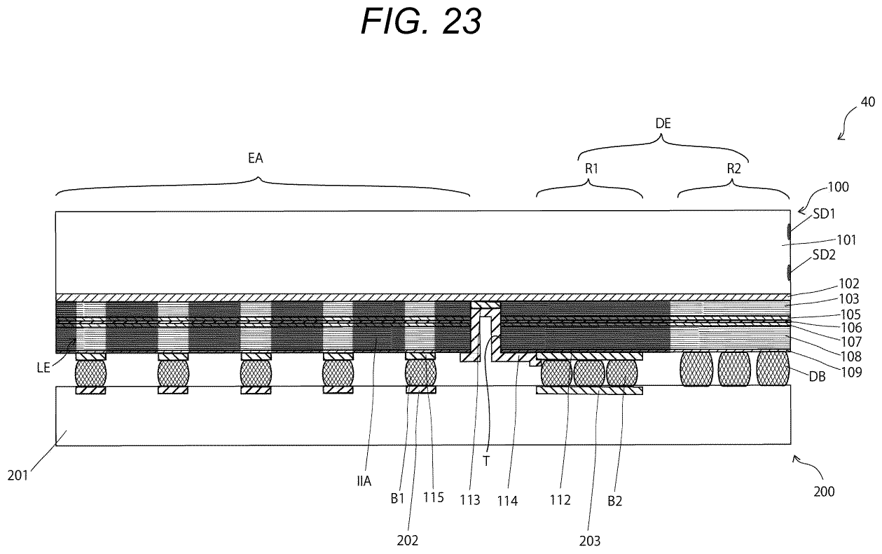

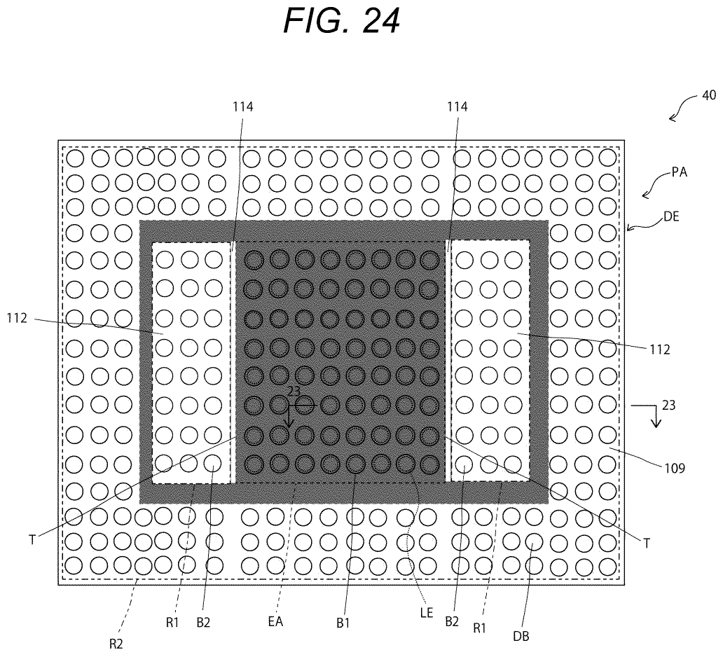

FIG. 23 is a cross-sectional view of a surface emitting device 40 according to Example 4 of one embodiment of the present technology. FIG. 24 is a bottom view of the surface emitting device 40 according to Example 4 of one embodiment of the present technology in a state where the mounting substrate 200 is omitted. FIG. 23 is a cross-sectional view taken along a line 23-23 in FIG. 24.

As illustrated in FIGS. 23 and 24, the surface emitting device 40 has a substantially similar configuration to the surface emitting device 10 according to Example 1 except that the surface emitting element 100 has a mesa-less structure and an ion implantation region IIA is provided instead of the oxidation confinement layer 104.

In the surface emitting device 40, each of the light emitting element part LE and the dummy element part DE includes the substrate 101, the first contact layer 102, the first semiconductor multilayer film reflector 103, the first cladding layer 105, the light emitting layer 106, the second cladding layer 107, the second semiconductor multilayer film reflector 108, and the second contact layer 109.

The ion implantation region IIA as a high resistance region or an insulating region is provided so as to surround a region immediately above the cathode electrode 115 in the light emitting element part LE. Here, the ion implantation region IIA is provided in a region excluding the first contact layer 102 in the laminating direction (vertical direction) of the light emitting element part LE. Also in here, a lateral current path is formed in the first contact layer 102 of the light emitting element part LE.

The ion species used for the ion implantation region IIA include, for example, H+, and B+, or the like.

A trench T is provided between the element region EA and the dummy element part DE. The bottom surface of the trench T coincides with the lower surface of the first contact layer 102. The intermediate electrode 113 is provided on the bottom surface of the trench T. One of one side surface and the other side surface facing each other of the trench T is a side surface of the element region EA, and the other is a side surface of the dummy element part DE. The ion implantation region IIA is provided on one side surface side and the other side surface side of the trench T facing each other. The trench means a “groove” in a narrow sense, but includes a “hole”, a “recess”, a “dent”, and the like in a broad sense.

The wiring 114 is provided so as to cover the peripheral portion of the trench T on the lower surface of the element region EA, the side surface of the trench T on the element region EA side, the side surface of the trench T on the dummy element part DE side, the intermediate electrode 113, and the peripheral portion of the trench T on the lower surface of the dummy element part DE. An end of a portion covering the lower surface of the dummy element part DE of the wiring 114 is in contact with the anode electrode 112. The wiring 114 constituted as described above ensures good conductivity between the intermediate electrode 113 in contact with the first contact layer 102 and the anode electrode 112.

### 5. Surface Emitting Device According to Example 5 of One Embodiment of the Present Technology

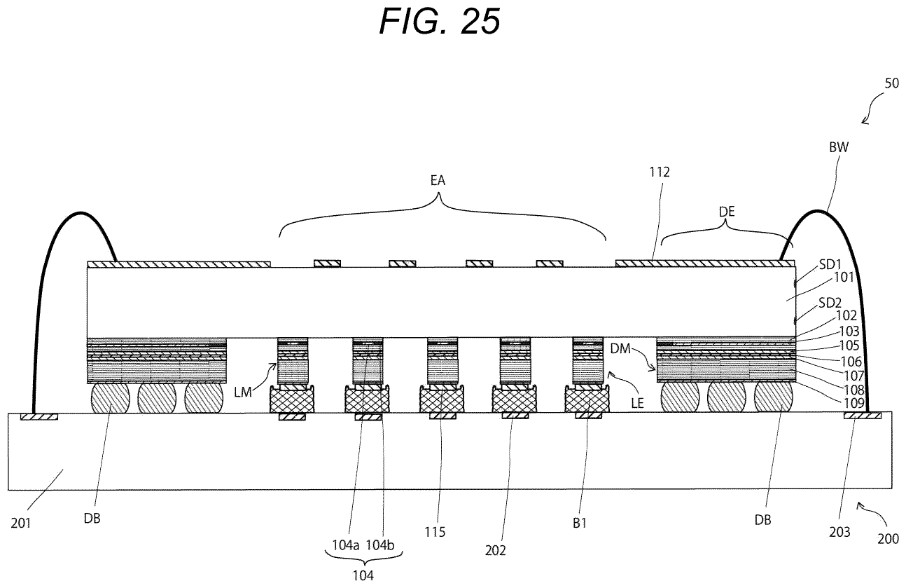

FIG. 25 is a cross-sectional view of a surface emitting device 50 according to Example 5 of one embodiment of the present technology.

The surface emitting device 50 has a substantially similar configuration to the surface emitting device 10 according to Example 1 except that the anode electrode 112 is provided on the back surface side (upper surface side) of the substrate 101 and the dummy element part DE does not have a region corresponding to the first region R1. Here, the substrate 101 includes, for example, a p-GaAs.

In the surface emitting device 50, the anode electrode 112 is provided on the back surface of the Substrate 101 so as to surround the light emitting region of the light emitting layer 106 in plan view. The anode electrode 112 is connected to the second electrode 203 of the mounting substrate 200 through a bonding wire BW.

### 6. Surface Emitting Device According to Example 6 of One Embodiment of the Present Technology

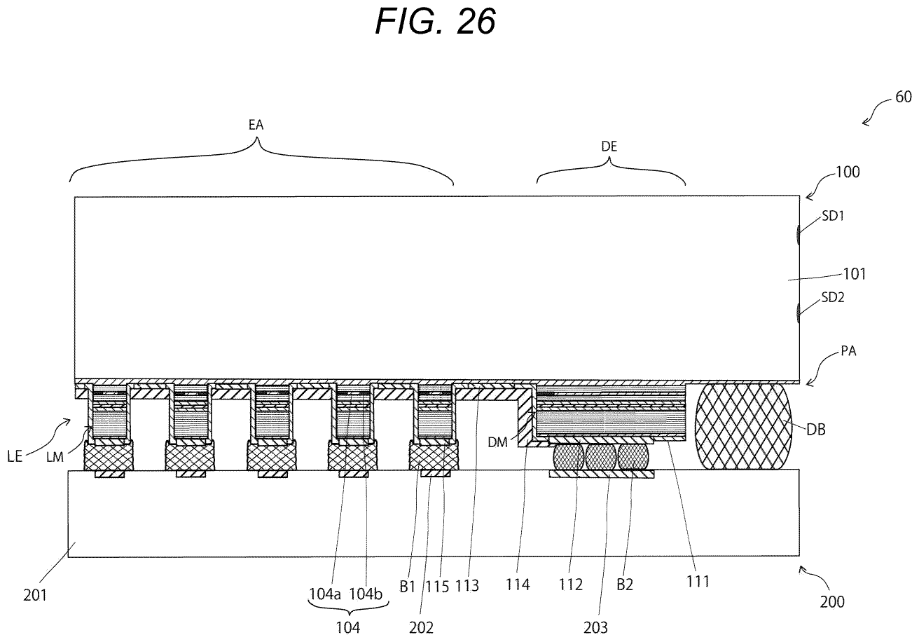

FIG. 26 is a cross-sectional view of a surface emitting device 60 according to Example 6 of one embodiment of the present technology.

The surface emitting device 60 has a substantially similar configuration to the surface emitting device 10 according to Example 1 except that the dummy element part DE does not have the outermost peripheral portion of the peripheral region PA, and the outermost peripheral portion and the mounting substrate 200 are bonded with the dummy bump DB interposed therebetween.

### 7. Surface Emitting Device According to Example 7 of One Embodiment of the Present Technology

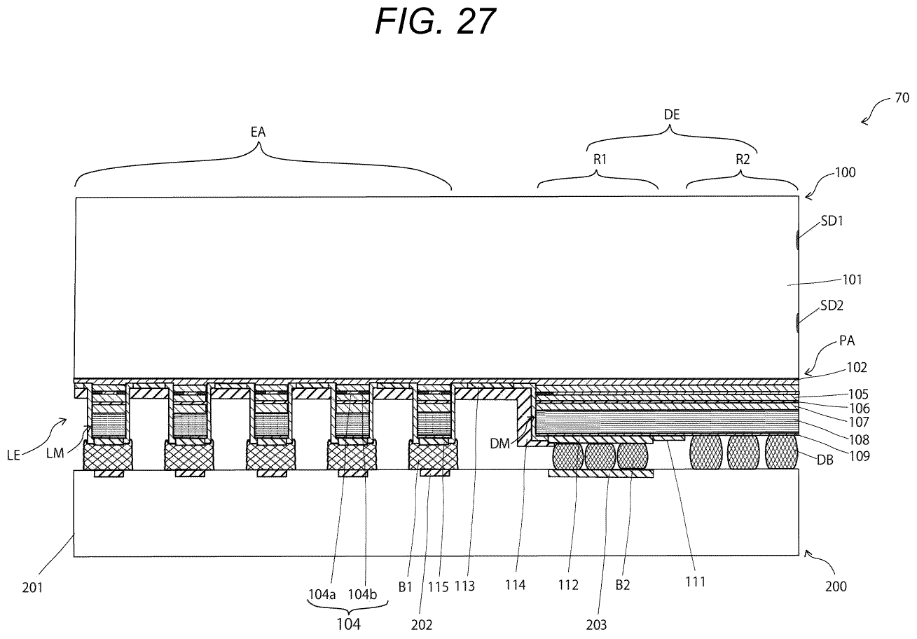

FIG. 27 is a cross-sectional view of a surface emitting device 70 according to Example 7 of one embodiment of the present technology.

As illustrated in FIG. 27, the surface emitting device 70 has a substantially similar configuration to the surface emitting device 10 according to Example 1 except that each of the light emitting element parts LE of the surface emitting element 100 is a back surface emission type light emitting diode (LED).

In the surface emitting device 70, as an example, the first semiconductor multilayer film reflector 103 is not provided, and the oxidation confinement layer 104 is provided in the first cladding layer 105.

In the surface emitting device 70, light emitted from the light emitting layer 106 of the light emitting element part LE to the upper side (the back surface side of the substrate 101) is combined with light emitted from the light emitting layer 106 to the lower side (the front surface side of the substrate 101) and reflected by the second semiconductor multilayer film reflector 108, and the combined light is emitted to the back surface side of the substrate 101.

According to the surface emitting device 70, a surface emitting device including a high-efficiency and high-output light emitting diode and achieving the similar effects as those of the surface emitting device 10 according to Example 1 can be realized.

### 8. Surface Emitting Device According to Example 8 of One Embodiment of the Present Technology

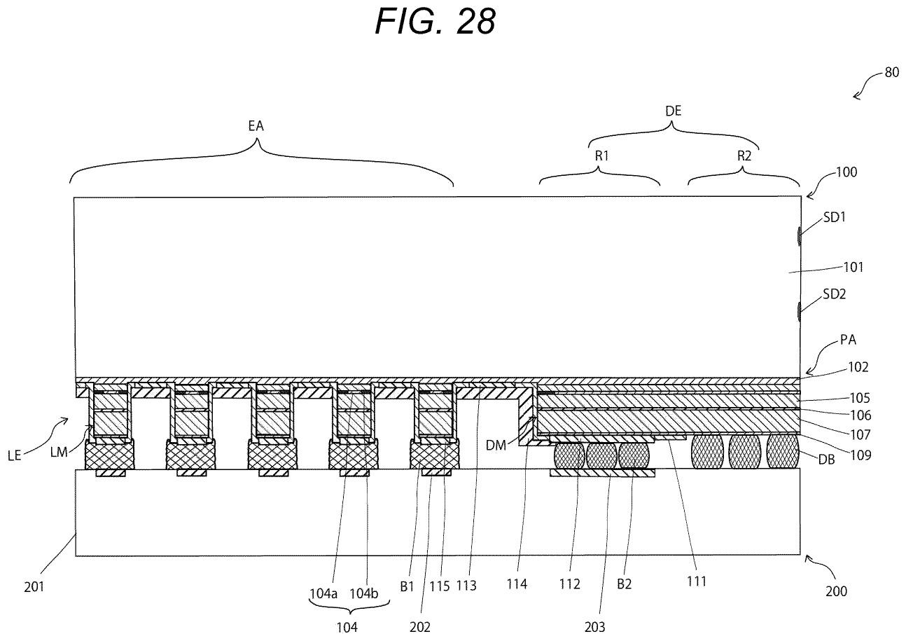

FIG. 28 is a cross-sectional view of a surface emitting device 80 according to Example 8 of one embodiment of the present technology.

As illustrated in FIG. 28, the surface emitting device 80 has a substantially similar configuration to the surface emitting device 10 according to Example 1 except that each of the light emitting element parts LE of the surface emitting element 100 is a back surface emission type light emitting diode (LED).

In the surface emitting device 80, as an example, the first and second semiconductor multilayer film reflectors 103 and 108 are not provided, and the oxidation confinement layer 104 is provided in the first cladding layer 105.

In the surface emitting device 80, light emitted from the light emitting layer 106 of the light emitting element part LE to the upper side (the back surface side of the substrate 101) is combined with light emitted from the light emitting layer 106 to the lower side (the front surface side of the substrate 101) and reflected by the cathode electrode 115, and the combined light is emitted to the back surface side of the substrate 101.

According to the surface emitting device 80, a surface emitting device including a high-efficiency light emitting diode and achieving the similar effects as those of the surface emitting device 10 according to Example 1 can be realized.

### 9. Surface Emitting Device According to Example 9 of One Embodiment of the Present Technology

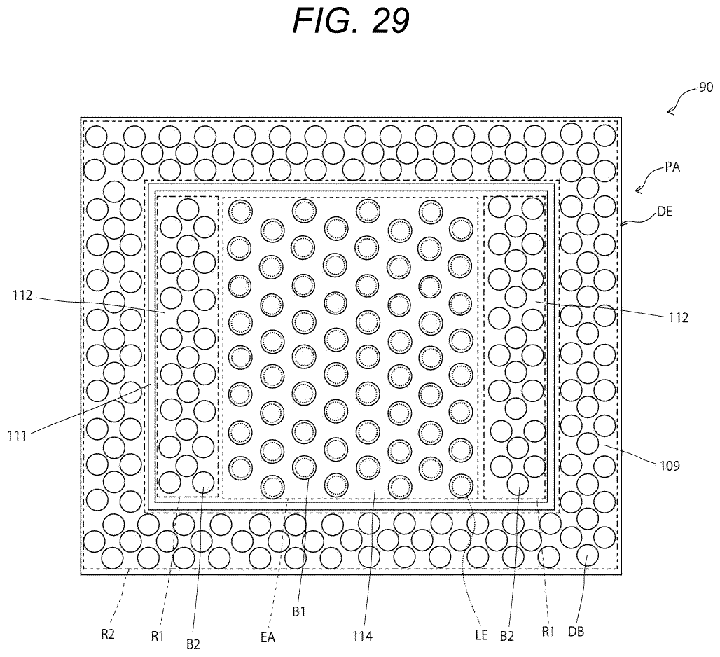

FIG. 29 is a bottom view of the surface emitting device 90 according to Example 9 of one embodiment of the present technology in a state where the mounting substrate 200 is omitted.

The surface emitting device 90 has a similar configuration to the surface emitting device 10 according to Example 1 except that the first bumps B1, the second bumps B2, and the dummy bumps DB are each arranged in a staggered manner. Note that, instead of the staggered arrangement, for example, random arrangement may be employed.

According to the surface emitting device 90, because each of the bumps can be densely arranged, there can be realized the surface emitting device 90 including the surface emitting element 100 in which element breakage and lowering in reliability are suppressed for a larger number of channels.

### 10. Surface Emitting Device According to Example 10 of One Embodiment of the Present Technology

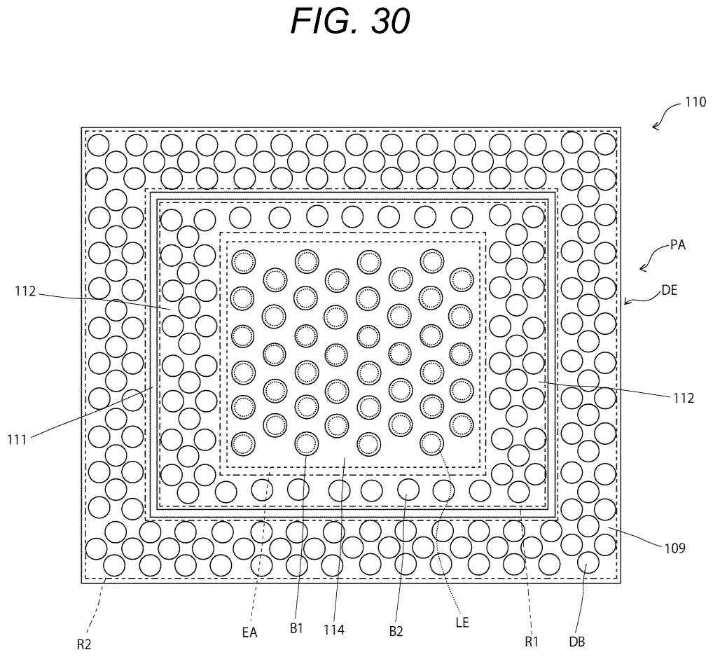

FIG. 30 is a bottom view of a surface emitting device 110 according to Example 10 of one embodiment of the present technology in a state where the mounting substrate 200 is omitted.

As illustrated in FIG. 30, the surface emitting device 110 has a similar configuration to the surface emitting device 90 according to Example 9 except that the first region R1 of the dummy element part DE has a shape of a circumference (for example, a rectangular frame shape) extending along the entire circumference of the outer periphery of the element region EA, and the second bumps B2 are provided along the entire circumference of the second region R2.

### 11. Surface Emitting Device According to Example 11 of One Embodiment of the Present Technology

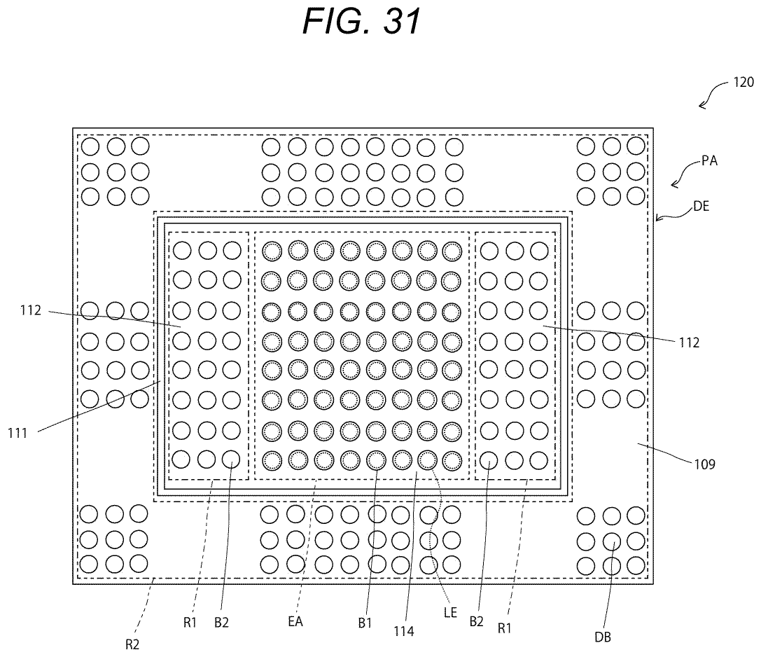

FIG. 31 is a bottom view of a surface emitting device 120 according to Example 11 of one embodiment of the present technology in a state where the mounting substrate 200 is omitted.

As illustrated in FIG. 31, the surface emitting device 120 has a similar configuration to the surface emitting device 10 according to Example 1 except that the dummy bumps DB are provided along a part of the second region R2 of the dummy element part DE in the circumferential direction.

In the surface emitting device 120, the plurality of dummy bumps DB is provided along each of the four corners, the central portion on the short side, and the central portion on the long side, of the second region R2.

According to the surface emitting device 120, the dummy bumps DB are not provided along a part of the second region R2, but the dummy bumps DB are arranged in a well-balanced manner with respect to the second region R2 as in the example of FIG. 31. Therefore, deformation of the surface emitting element at the time of bump bonding can be suppressed.

### 12. Surface Emitting Device According to Example 12 of One Embodiment of the Present Technology

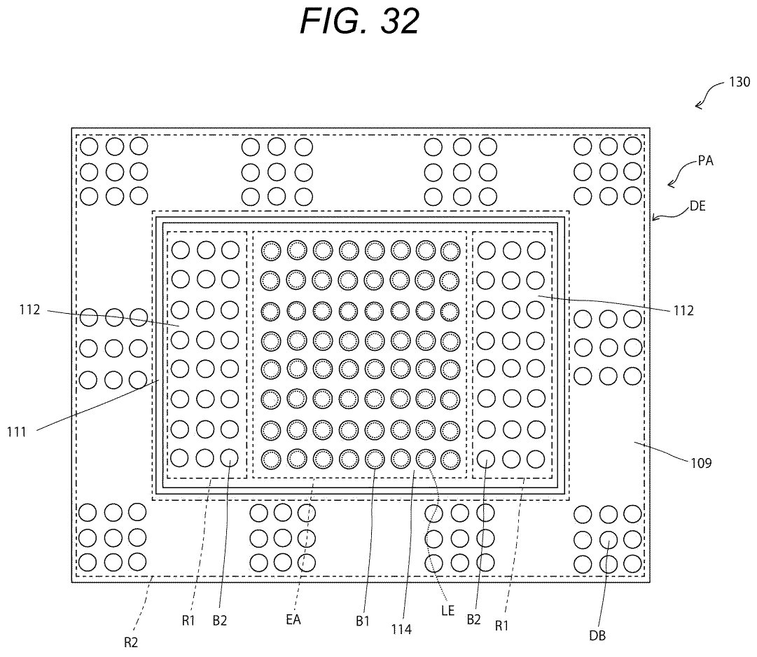

FIG. 32 is a bottom view of a surface emitting device 130 according to Example 12 of one embodiment of the present technology in a state where the mounting substrate 200 is omitted.

As illustrated in FIG. 32, the surface emitting device 130 has a similar configuration to the surface emitting device 10 according to Example 1 except that the dummy bumps DB are provided along a part of the second region R2 of the dummy element part DE in the circumferential direction.

In the surface emitting device 130, the plurality of dummy bumps DB is provided along each of a plurality of portions spaced apart at equal intervals including four corners in the circumferential direction of the second region R2.

According to the surface emitting device 130, the dummy bumps DB are not provided along a part of the second region R2, but the dummy bumps DB are arranged in a well-balanced manner with respect to the second region R2 as in the example of FIG. 32. Therefore, deformation of the surface emitting element at the time of bump bonding can be suppressed.

### 13. Surface Emitting Device According to Example 13 of One Embodiment of the Present Technology

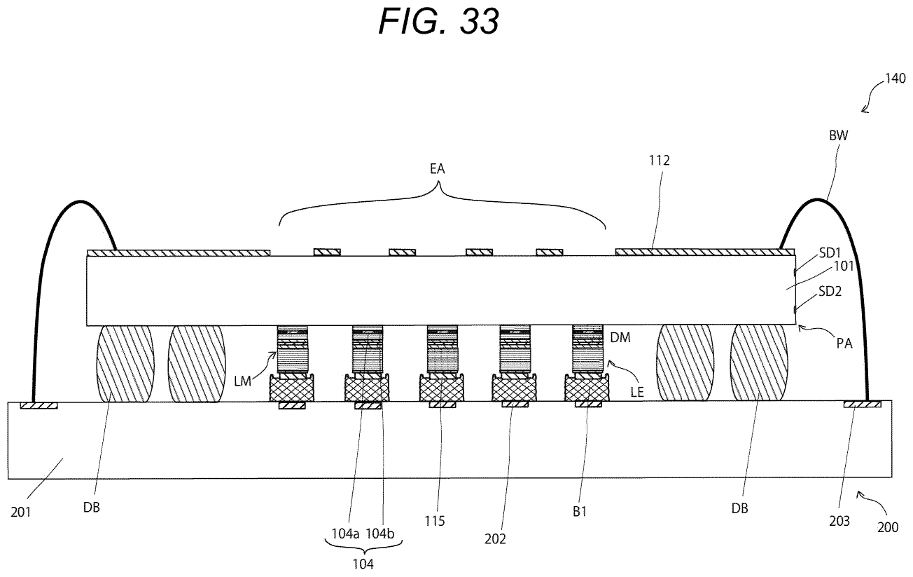

FIG. 33 is a cross-sectional view of a surface emitting device 140 according to Example 13 of one embodiment of the present technology.

The surface emitting device 140 has a substantially similar configuration to the surface emitting device 50 according to Example 5 except that the dummy element part DE is not provided.

In the surface emitting device 140, the plurality of dummy bumps DB is interposed as spacers between the outermost peripheral portion of the peripheral region PA of the surface emitting element 100 where the structure (for example, the dummy mesa DM) is not provided and the mounting substrate 200.

### 14. Surface Emitting Device According to Example 14 of One Embodiment of the Present Technology

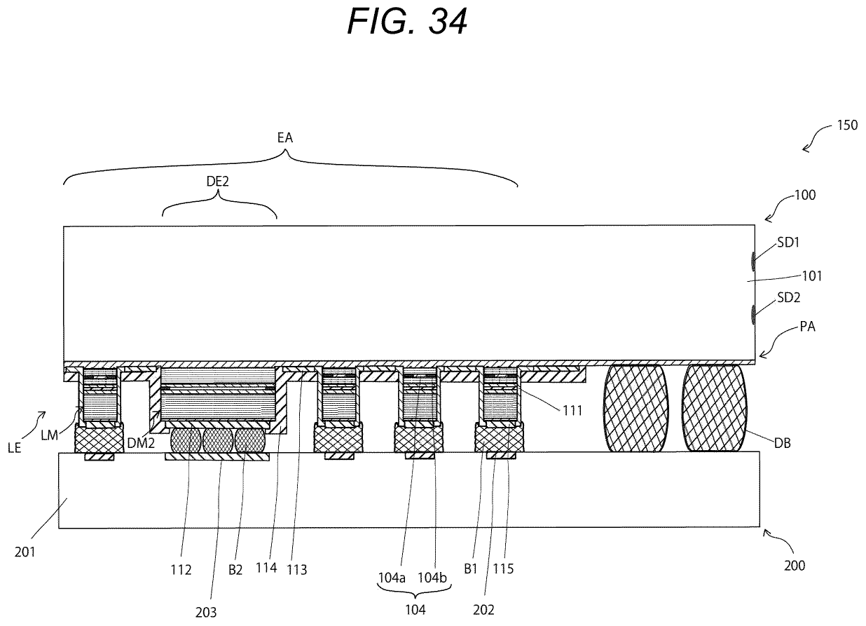

FIG. 34 is a cross-sectional view of a surface emitting device 150 according to Example 14 of one embodiment of the present technology.

The surface emitting device 150 has a substantially similar configuration to the surface emitting device 30 according to Example 3 except that the first dummy element part DE1 is not provided.

In the surface emitting device 150, the plurality of dummy bumps DB is interposed as spacers between the outermost peripheral portion of the peripheral region PA of the surface emitting element 100 where the structure (for example, the dummy mesa DM) is not provided and the mounting substrate 200.

### 15. Modification of the Present Technology

The present technology is not limited to each of Examples of one embodiment described above, and can be appropriately changed.

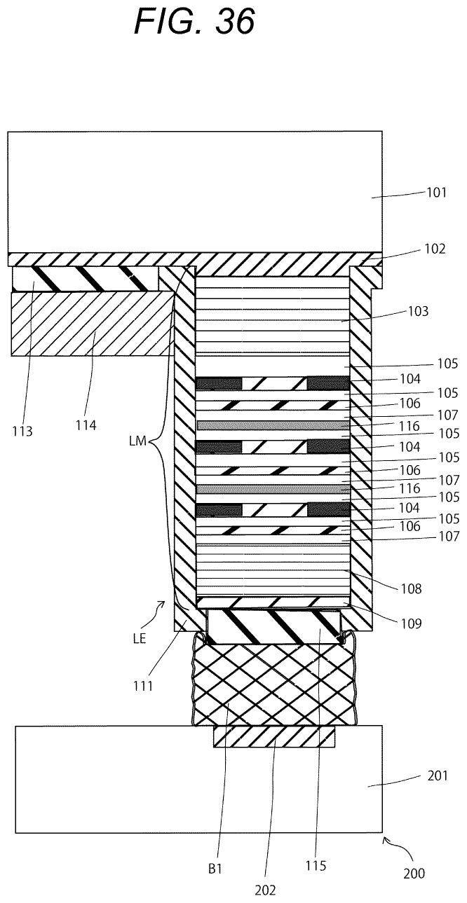

For example, as the light emitting element part of the surface emitting device according to each of Examples described above, the light emitting element part LE of a modification illustrated in FIG. 36 may be used. The light emitting element part LE of the present modification is a multi-junction VCSEL. In the present modification, the light emitting element part LE includes a plurality of (for example, three) the light emitting layers 106 laminated on each other, the oxidation confinement layers 104 each disposed on the p side (upper side) of each light emitting layer 106, and tunnel junction layers 116 each disposed between the two adjacent light emitting layers 106. Each light emitting layer 106 is sandwiched between the first cladding layer 105 immediately above and the second cladding layer 107 immediately below. Each oxidation confinement layer 104 is sandwiched between the first cladding layer 105 immediately above and the first cladding layer 105 immediately below. Each tunnel junction layer 116 is sandwiched between the second cladding layer 107 immediately above and the first cladding layer 105 immediately below. By using the light emitting element part LE of the present modification as the light emitting element part of the surface emitting device according to each of Examples described above, the output can be increased. Therefore, the surface emitting device is particularly suitable as a light source of a distance measurement device (LiDAR) mounted on a mobile body (for example, a vehicle) described later. Note that, in the present modification, the number of the light emitting layers 106, the oxidation confinement layers 104, and the tunnel junction layers 116 can be appropriately changed.

For example, the spacer SP may include a single structure.

For example, the spacer SP may include at least one Structure other than the bump.

In each of Examples described above, the surface emitting element may not include at least one of the first and second contact layers 102 and 109.

Instead of or in addition to the inside of the first semiconductor multilayer film reflector 103, the oxidation confinement layer 104 may be provided in at least one of the inside of the first contact layer 102, between the first contact layer 102 and the first semiconductor multilayer film reflector 103, between the first semiconductor multilayer film reflector 103 and the first cladding layer 105, the inside of the first cladding layer 105, between the first cladding layer 105 and the light emitting layer 106, between the light emitting layer 106 and the second cladding layer 107, the inside of the second cladding layer 107, between the second cladding layer 107 and the second semiconductor multilayer film reflector 108, the inside of the second semiconductor multilayer film reflector 108, between the second semiconductor multilayer film reflector 108 and the second contact layer 109, and the inside of the second contact layer 109.

In each of Examples described above, the light emitting element part array of the surface emitting element has the light emitting element part LE arranged two-dimensionally, but for example, the light emitting element part LE may be arranged one-dimensionally.

For example, the current confinement in the surface emitting element is not limited to the current confinement by the oxidation confinement layer 104 or the ion implantation region IIA. For example, the current confinement may be performed by a quantum well intermixing (QWI) that provides a bandgap energy difference between the inside and outside of the aperture by Ga vacancy diffusion to confine carriers, a tunnel junction, a buried tunnel junction, or the like. A plurality of current confinement structures may be used in combination. For example, the non-oxidized region 104a of the oxidation confinement layer 104 may be surrounded by the ion implantation region IIA.

For example, the substrate 101 may be an Si substrate, a Ge substrate, a GaN substrate, an InP substrate, or the like. In any case, the semiconductor layer laminated on the substrate 101 is preferably appropriately selected so as to be lattice-matched with the material of the substrate 101. For the surface emitting element, a material having any emission wavelength included in the wavelength band of 200 to 2000 nm can be used.

The surface emitting element is not limited to the semiconductor multilayer film reflector, but may include a reflector including one or a combination of two or more types selected from a semiconductor, a dielectric, and a metal.

In the surface emitting device in each of Examples described above, the conductivity types (p-type and n-type) of the first and second semiconductor structures may be reversed. In this case, the positional relationship between the anode electrode and the cathode electrode needs to be reversed.

A part of the configurations of the surface emitting devices in Examples described above may be combined within a range not contradictory to each other.

In each of Examples described above, the material, thickness, width, shape, size, and the like of each constituent element of the surface emitting element and the mounting substrate constituting the surface emitting device can be appropriately changed within a range of functioning as a surface emitting device.

### 16. Application Example for Electronic Apparatus

The technology (present technology) according to the present disclosure can be applied to various products (electronic apparatuses). For example, the technology according to the present disclosure may be implemented as any type of mobile body such as an automobile, an electric vehicle, a hybrid electric vehicle, a motorcycle, a bicycle, a personal mobility, an airplane, a drone, a ship, or a robot, or as a device mounted on a low power consumption apparatus (for example, a smartphone, a smartwatch, a tablet, a mouse, or the like).

The surface emitting device according to the present technology can also be applied as, for example, a light source of a device that forms or displays an image by light (for example, a printer, a copier, a projector, a head-mounted display, a head-up display, or the like).

### 17. Example in Which Surface Emitting Device is Applied to Distance Measurement Device

Hereinafter, an application example of the surface emitting device 10 according to Example 1 will be described.

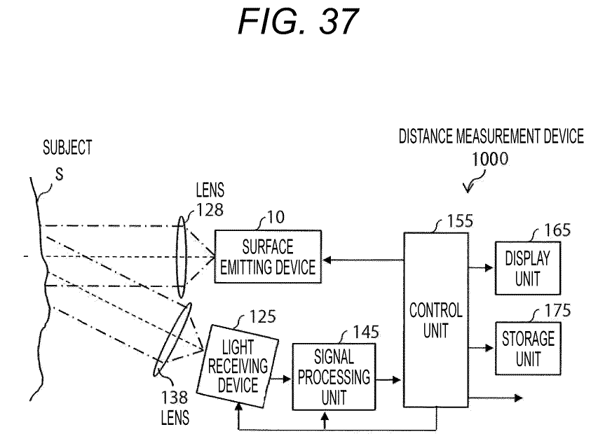

FIG. 37 illustrates an example of a schematic configuration of a distance measurement device 1000 (ranging device) including the surface emitting device 10, as an example of an electronic apparatus according to the present technology. The distance measurement device 1000 measures the distance to a subject S by a time of flight (TOF) method. The distance measurement device 1000 includes the surface emitting device 10. The distance measurement device 1000 includes, for example, the surface emitting device 10, a light receiving device 125, lenses 128 and 138, a signal processing unit 145, a control unit 155, a display unit 165, and a storage unit 175.

The light receiving device 125 receives light emitted from the surface emitting device 10 and reflected by the subject S (object). That is, the light receiving device 125 detects the light reflected by the subject S. The lens 128 is a lens for collimating the light emitted from the surface emitting device 10, and is, for example, a collimating lens. The lens 138 is a lens for collecting the light reflected by the subject S and guiding the light to the light receiving device 125, and is, for example, a condenser lens.

The signal processing unit 145 is a circuit for generating a signal corresponding to a difference between a signal input from the light receiving device 125 and a reference signal input from the control unit 155. The control unit 155 includes, for example, a time to digital converter (TDC). The reference signal may be a signal input from the control unit 155, or may be an output signal of a detection unit that directly detects the output of the surface emitting device 10. The control unit 155 is, for example, a processor that controls the surface emitting device 10, the light receiving device 125, the signal processing unit 145, the display unit 165, and the storage unit 175. The control unit 155 is a circuit that measures the distance to the subject S on the basis of the signal generated by the signal processing unit 145. The control unit 155 generates a video signal for displaying information on the distance to the subject S, and outputs the video signal to the display unit 165. The display unit 165 displays information on the distance to the subject S on the basis of the video signal input from the control unit 155. The control unit 155 stores information on the distance to the subject S in the storage unit 175.

In the present application example, instead of the surface emitting device 10, any of the surface emitting devices 20, 30, 40, 50, 60, 70, 80, 90, 110, 120, and 130 can be applied to the distance measurement device 1000.

### 18. Example in Which Distance Measurement Device is Mounted on Mobile Body>

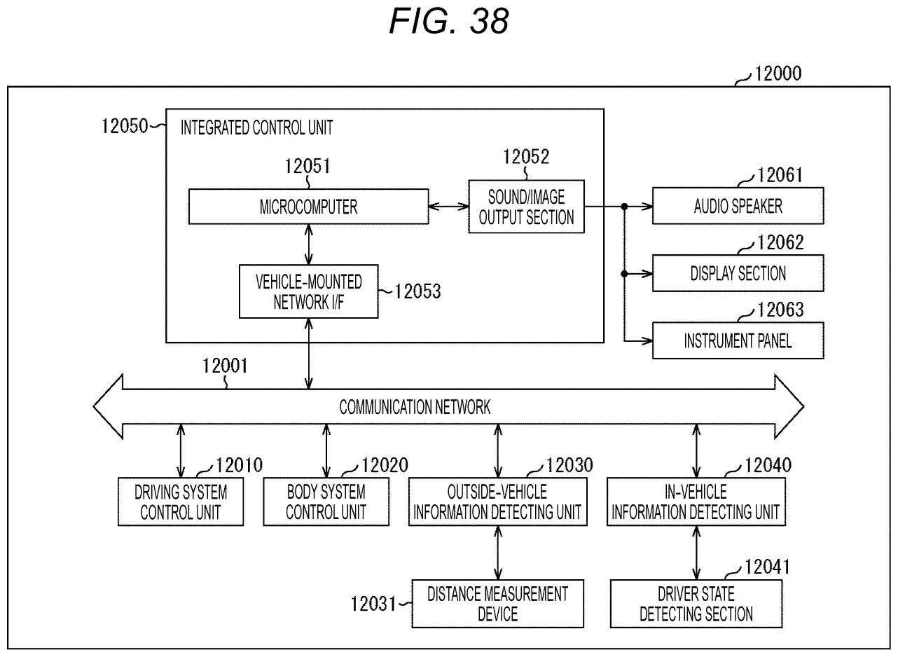

FIG. 38 is a block diagram illustrating an example of a schematic configuration of a vehicle control system that is an example of a mobile body control system to which the technology according to the present disclosure can be applied.

A vehicle control system 12000 includes a plurality of electronic control units connected to each other via a communication network 12001. In the example illustrated in FIG. 38, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as functional configurations of the integrated control unit 12050.

The driving system control unit 12010 controls operation of devices related to a driving system of a vehicle in accordance with various programs. For example, the driving system control unit 12010 functions as a control device for a driving force generating device for generating driving force of the vehicle, such as an internal combustion engine or a driving motor, a driving force transmitting mechanism for transmitting the driving force to wheels, a steering mechanism for adjusting a steering angle of the vehicle, a braking device for generating braking force of the vehicle, and the like.

The body system control unit 12020 controls operations of various devices provided to a vehicle body in accordance with various programs. For example, the body system control unit 12020 functions as a control device for a keyless entry system, a smart key system, a power window device, or various lamps such as a headlamp, a back-up lamp, a brake lamp, a turn indicator, or a fog lamp. In this case, a radio wave transmitted from a mobile device that substitutes for a key or signals of various switches can be input to the body system control unit 12020. The body system control unit 12020 receives these input radio waves or signals, and controls a door lock device, the power window device, the lamps, or the like of the vehicle.

The outside-vehicle information detecting unit 12030 detects information on the outside of the vehicle mounted with the vehicle control system 12000. For example, a distance measurement device 12031 is connected to the outside-vehicle information detecting unit 12030. The distance measurement device 12031 includes the distance measurement device 1000 described above. The outside-vehicle information detecting unit 12030 causes the distance measurement device 12031 to measure a distance to an object (subject S) outside the vehicle, and acquires distance data obtained by the measurement. The outside-vehicle information detecting unit 12030 may perform object detection processing of a person, a vehicle, an obstacle, a sign, or the like on the basis of the acquired distance data.

The in-vehicle information detecting unit 12040 detects information on the inside of the vehicle. The in-vehicle information detecting unit 12040 is, for example, connected with a driver state detecting section 12041 that detects the state of a driver. The driver state detecting section 12041 includes, for example, a camera that images the driver, and on the basis of detection information input from the driver state detecting section 12041, the in-vehicle information detecting unit 12040 may calculate a degree of fatigue of the driver or a degree of concentration of the driver, or may determine whether or not the driver is dozing.

The microcomputer 12051 can calculate a control target value for the driving force generating device, the steering mechanism, or the braking device on the basis of the information on the inside or outside of the vehicle, the information being obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS), the functions including vehicle collision avoidance or shock mitigation, following driving based on a following distance, vehicle speed maintaining driving, vehicle collision warning, vehicle lane departure warning, and the like.

Furthermore, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information on the surroundings of the vehicle, the information being obtained by the outside-vehicle information detecting unit 12030 or the in-vehicle information detecting unit 12040.

Furthermore, the microcomputer 12051 can output a control command to the body system control unit 12020 on the basis of the information on the outside of the vehicle obtained by the outside-vehicle information detecting unit 12030. For example, the microcomputer 12051 can perform cooperative control intended to prevent the glare, such as switching from a high beam to a low beam, by controlling the headlamp in accordance with a position of a preceding vehicle or an oncoming vehicle detected by the outside-vehicle information detecting unit 12030.

The sound/image output section 12052 transmits an output signal of at least one of a sound or an image to an output device that can visually or auditorily notify an occupant or the outside of the vehicle of information. In the example of FIG. 38, an audio speaker 12061, a display section 12062, and an instrument panel 12063 are illustrated as the output device. The display section 12062 may include, for example, at least one of an on-board display or a head-up display.

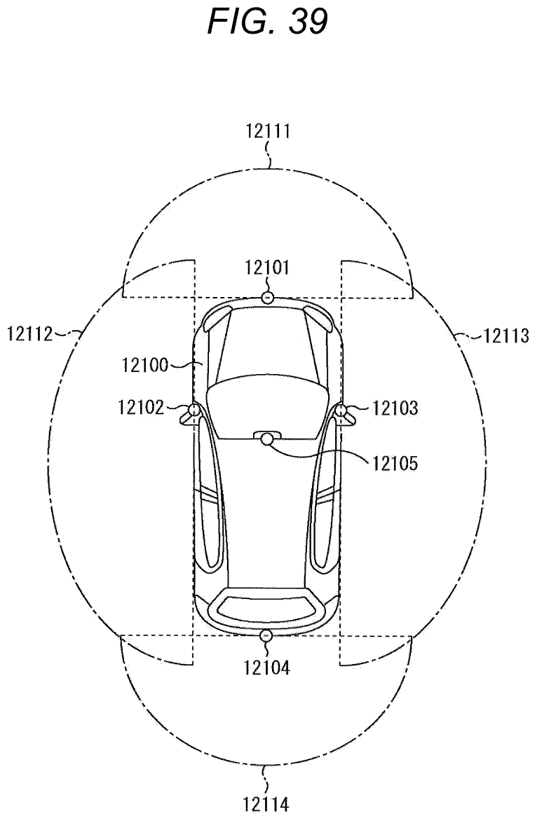

FIG. 39 is a diagram illustrating an example of installation positions of the distance measurement device 12031.

In FIG. 39, a vehicle 12100 includes distance measurement devices 12101, 12102, 12103, 12104, and 12105 as the distance measurement device 12031.

The distance measurement devices 12101, 12102, 12103, 12104, and 12105 are provided, for example, at positions such as a front nose, sideview mirrors, a rear bumper, a back door, and an upper portion of a windshield in a vehicle interior of the vehicle 12100. The distance measurement device 12101 provided at the front nose and the distance measurement device 12105 provided at the upper portion of the windshield in the vehicle interior mainly acquire data of the front side of the vehicle 12100. The distance measurement devices 12102 and 12103 provided at the sideview mirrors mainly acquire data of the sides of the vehicle 12100. The distance measurement device 12104 provided at the rear bumper or the back door mainly acquires data of the rear side of the vehicle 12100. The data on the front side acquired by the distance measurement devices 12101 and 12105 is mainly used to detect a preceding vehicle, a pedestrian, an obstacle, a traffic light, a traffic sign, or the like.

Note that FIG. 39 illustrates an example of detection ranges of the distance measurement devices 12101 to 12104. A detection range 12111 indicates a detection range of the distance measurement device 12101 provided at the front nose, detection ranges 12112 and 12113 indicate detection ranges of the distance measurement devices 12102 and 12103 provided at the sideview mirrors, respectively, and a detection range 12114 indicates a detection range of the distance measurement device 12104 provided at the rear bumper or the back door.

For example, by the microcomputer 12051 obtaining a distance to each three-dimensional object within the detection ranges 12111 to 12114 and a temporal change in the distance (relative speed with respect to the vehicle 12100) on the basis of the distance data obtained from the distance measurement devices 12101 to 12104, particularly the nearest three-dimensional object present on a traveling path of the vehicle 12100, which travels in substantially the same direction as the vehicle 12100 at a predetermined speed (for example, equal to or more than 0 km/h), can be extracted as a preceding vehicle. Moreover, the microcomputer 12051 can set a following distance to be maintained relative to a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, on the basis of the distance data obtained from the distance measurement devices 12101 to 12104, the microcomputer 12051 can extract three-dimensional object data regarding three-dimensional objects while classifying the data into two-wheeled vehicles, standard-sized vehicles, large-sized vehicles, pedestrians, and other three-dimensional objects such as utility poles, and use the three-dimensional object data for automatic avoidance of obstacles. For example, the microcomputer 12051 identifies obstacles around the vehicle 12100 as obstacles that the driver of the vehicle 12100 can recognize visually and obstacles that are difficult for the driver of the vehicle to recognize visually. Then, the microcomputer 12051 determines a collision risk indicating a risk of collision with each obstacle, and in a situation in which the collision risk is greater than or equal to a set value and there is a possibility of collision, the microcomputer 12051 can perform driving assistance to avoid collision by outputting a warning to the driver via the audio speaker 12061 or the display section 12062 and by performing forced deceleration or avoidance steering via the driving system control unit 12010.

An example of the mobile body control system to which the technology according to the present disclosure can be applied has been described above. The technology according to the present disclosure can be applied to the distance measurement device 12031 among the configurations described above.

Furthermore, the present technology can also adopt the following configurations.
(1) A surface emitting device including:
a surface emitting element including an element region and a peripheral region around the element region; and
a mounting substrate on which the surface emitting element is mounted, in which
the element region includes a light emitting element part provided with an electrode on a mounting substrate side,
the electrode is bonded to the mounting substrate with a bump interposed between the electrode and the mounting substrate, and
the peripheral region and the mounting substrate have a spacer provided between the peripheral region and the mounting substrate.
(2) The surface emitting device according to (1), in which the spacer is interposed between an outermost peripheral portion of the peripheral region and the mounting substrate.
(3) The surface emitting device according to (1) or (2), in which the peripheral region has a dummy element part.
(4) The surface emitting device according to (3), in which the dummy element part includes the outermost peripheral portion.
(5) The surface emitting device according to any one of (2) to (4), in which
the outermost peripheral portion extends along at least a part of an outer periphery of the element region, and
the spacer is provided along at least a part of the outermost peripheral portion in an extending direction.
(6) The surface emitting device according to (5), in which the outermost peripheral portion extends along an entire circumference of an outer periphery of the element region.
(7) The surface emitting device according to (5) or (6), in which the spacer has a plurality of portions aligned in the extending direction.
(8) The surface emitting device according to any one of (1) to (7), in which the spacer includes a dummy bump.
(9) The surface emitting device according to any one of (1) to (8), in which the surface emitting element has an emission surface which is a surface on an opposite side to the mounting substrate side, the emission surface being a flat surface.
(10) The surface emitting device according to any one of (1) to (9), in which the surface emitting element has a modified layer on a side surface.
(11) The surface emitting device according to any one of (1) to (10), in which,
with respect to a direction orthogonal to an in-plane direction, the electrode has a surface on the mounting substrate side, the surface being located closer to the mounting substrate than a surface of the outermost peripheral portion of the peripheral region on the mounting substrate side, and
the spacer has a thickness that is thicker than a thickness of the bump.
(12) The surface emitting device according to any one of (1) to (11), in which
the peripheral region has a dummy element part and the element region has a dummy element part, the dummy element part of the peripheral region and/or the dummy element part of the element region having the mounting substrate side provided with another electrode, and
the another electrode is bonded to the mounting substrate with another bump interposed between the another electrode and the mounting substrate.
(13) The surface emitting device according to (11), in which
the element region includes a plurality of the light emitting element parts separated in an in-plane direction, and
the another electrode is a common electrode provided in common for the plurality of light emitting element parts.
(14) The surface emitting device according to any one of (8) to (13), in which each of the bump and the dummy bump includes a material that is not easily crushed by pressurization.
(15) The surface emitting device according to any one of (8) to (14), in which the bump and the dummy bump include the same conductive material.
(16) The surface emitting device according to any one of (1) to (15), in which
the peripheral region includes a dummy element part, and
each of the light emitting element part and the dummy element part includes
first and second semiconductor structures laminated on each other, and
a light emitting layer disposed between the first and second semiconductor structures.
(17) A manufacturing method of a surface emitting device, the manufacturing method including:
a step of forming a surface emitting element including an element region having a light emitting element part and a peripheral region of the element region; and
a step of interposing a spacer between the peripheral region and a mounting substrate and bonding an electrode provided on a mounting substrate side of the light emitting element part and the mounting substrate with a bump interposed between the electrode and the mounting substrate.
(18) The manufacturing method of the surface emitting device according to (17), in which the spacer includes a dummy bump.
(19) The manufacturing method of the surface emitting device according to (17) or (18), in which the step of bonding is performed by pressing an emission surface toward the mounting substrate side, the emission surface being a surface of the surface emitting element on an opposite side to the mounting substrate side.
(20) The manufacturing method of the surface emitting device according to any one of (17) to (19), in which,
in the step of forming, a plurality of the surface emitting elements is collectively formed such that the peripheral regions are adjacent to each other, and
after the step of forming and before the step of bonding, the manufacturing method includes a step of singulating the plurality of surface emitting elements by stealth dicing.

### REFERENCE SIGNS LIST

10, 20, 30, 40, 50, 60, 70, 80, 90, 110, 120, 130 Surface emitting device
100 Surface emitting element
106 Light emitting layer
115 Cathode electrode (Electrode)
112 Anode electrode (Another electrode)
200 Mounting substrate
EA Element region
PA Peripheral region
LE Light emitting element part
B1 First bump (Bump)
B2 Second bump (Another bump)
DE Dummy element part
SP Spacer
DB Dummy bump
SS1 First semiconductor structure
SS2 Second semiconductor structure
SD1 First modified layer (Modified layer)
SD2 Second modified layer (Modified layer)

1. A surface emitting device comprising:
a surface emitting element including an element region and a peripheral region around the element region; and
a mounting substrate on which the surface emitting element is mounted, wherein
the element region includes a light emitting element part provided with an electrode on a mounting substrate side,
the electrode is bonded to the mounting substrate with a bump interposed between the electrode and the mounting substrate, and
the peripheral region and the mounting substrate have a spacer provided between the peripheral region and the mounting substrate.

2. The surface emitting device according to claim 1, wherein the spacer is interposed between an outermost peripheral portion of the peripheral region and the mounting substrate.

3. The surface emitting device according to claim 2, wherein the peripheral region has a dummy element part.

4. The surface emitting device according to claim 3, wherein the dummy element part includes the outermost peripheral portion.

5. The surface emitting device according to claim 2, wherein
the outermost peripheral portion extends along at least a part of an outer periphery of the element region, and
the spacer is provided along at least a part of the outermost peripheral portion in an extending direction.

6. The surface emitting device according to claim 5, wherein the outermost peripheral portion extends along an entire circumference of an outer periphery of the element region.

7. The surface emitting device according to claim 5, wherein the spacer has a plurality of portions aligned in the extending direction.

8. The surface emitting device according to claim 1, wherein the spacer includes a dummy bump.

9. The surface emitting device according to claim 1, wherein the surface emitting element has an emission surface which is a surface on an opposite side to the mounting substrate side, the emission surface being a flat surface.

10. The surface emitting device according to claim 1, wherein the surface emitting element has a modified layer on a side surface.

11. The surface emitting device according to claim 1, wherein,
with respect to a direction orthogonal to an in-plane direction, the electrode has a surface on the mounting substrate side, the surface being located closer to the mounting substrate than a surface of the outermost peripheral portion of the peripheral region on the mounting substrate side, and
the spacer has a thickness that is thicker than a thickness of the bump.

12. The surface emitting device according to claim 1, wherein
the peripheral region has a dummy element part and the element region has a dummy element part, the dummy element part of the peripheral region and/or the dummy element part of the element region having the mounting substrate side provided with another electrode, and
the another electrode is bonded to the mounting substrate with another bump interposed between the another electrode and the mounting substrate.

13. The surface emitting device according to claim 12, wherein
the element region includes a plurality of the light emitting element parts separated in an in-plane direction, and
the another electrode is a common electrode provided in common for the plurality of light emitting element parts.

14. The surface emitting device according to claim 8, wherein each of the bump and the dummy bump includes a material that is not easily crushed by pressurization.

15. The surface emitting device according to claim 8, wherein the bump and the dummy bump include a same conductive material.

16. The surface emitting device according to claim 1, wherein
the peripheral region includes a dummy element part, and
each of the light emitting element part and the dummy element part includes
first and second semiconductor structures laminated on each other, and
a light emitting layer disposed between the first and second semiconductor structures.

17. A manufacturing method of a surface emitting device, the manufacturing method comprising:
a step of forming a surface emitting element including an element region having a light emitting element part and a peripheral region of the element region; and
a step of interposing a spacer between the peripheral region and a mounting substrate and bonding an electrode provided on a mounting substrate side of the light emitting element part and the mounting substrate with a bump interposed between the electrode and the mounting substrate.

18. The manufacturing method of the surface emitting device according to claim 17, wherein the spacer includes a dummy bump.

19. The manufacturing method of the surface emitting device according to claim 17, wherein the step of bonding is performed by pressing an emission surface toward the mounting substrate side, the emission surface being a surface of the surface emitting element on an opposite side to the mounting substrate side.

20. The manufacturing method of the surface emitting device according to claim 17, wherein,
in the step of forming, a plurality of the surface emitting elements is collectively formed such that the peripheral regions are adjacent to each other, and
after the step of forming and before the step of bonding, the manufacturing method comprises a step of singulating the plurality of surface emitting elements by stealth dicing.
